(19) United States
(12) Patent Application Publication
(10) Pub. No.: US 2008/0038675 A1
(43) Pub. Date: Feb. 14, 2008

(54) Exposure Method, Exposure Apparatus, Exposure System and Device Manufacturing Method

(75) Inventor: Hiroyuki Nagasaka, Kumagaya-shi (JP)

Correspondence Address: OLIFF & BERRIDGE, PLC, P.O. BOX 320850, ALEXANDRIA, VA, 22320-4850, US

(73) Assignee: Nikon Corporation, Tokyo (JP)

(21) Appl. No.: 10/589,962

(22) PCT Filed: Feb. 18, 2005
(86) PCT No.: PCT/JP05/02538

§ 371 Date: Aug. 18, 2006

(30) Foreign Application Priority Data
Feb. 20, 2004 (JP) 2004-045286

(51) Int. Cl. G03B 27/42; G03F 7/20; H01L 21/027

(52) U.S. Cl. 430/322; 355/53

(57) ABSTRACT

When exposing a same resist layer of a wafer a plurality of times, at least in one exposure of the plurality of exposures, by filling a space between a projection optical system, which projects an exposure light on the wafer, and the wafer with water by a liquid supply/drainage unit, a substantial wavelength of exposure light that reaches the wafer is made to differ from a substantial wavelength of exposure light in another exposure. Accordingly, exposure with high precision and high throughput can be achieved.

### TECHNICAL FIELD

The present invention relates to exposure methods, exposure apparatus, exposure systems, and device manufacturing methods, and more particularly, to an exposure method, an exposure apparatus, and an exposure system, in which exposure is performed on the same photosensitive object a plurality of times, and a device manufacturing method using the exposure method, the exposure apparatus or the exposure system.

### BACKGROUND ART

Conventionally, in a lithography process where an electronic device such as a semiconductor device (an integrated circuit) or a liquid crystal display device is manufactured, a projection exposure apparatus is used that transfers an image of a pattern of a mask or a reticle (hereinafter, generally referred to as a “reticle”) onto each shot area of a photosensitive substrate such as a wafer or a glass plate (hereinafter, referred to as a “substrate” or a “wafer”), on which a resist (photosensitive agent) is coated, via a projection optical system. As this type of projection exposure apparatus, conventionally, a reduction projection exposure apparatus (the so-called stepper) by a step-and-repeat method has been mainly used, but a projection exposure apparatus by a step-and-scan method (the so-called scanning stepper (also called as a scanner)) where exposure is performed while a reticle and a wafer are synchronously moved in a predetermined scanning direction is also recently drawing attention.

Normally, in the projection exposure apparatus above, the resolution of the apparatus improves as the wavelength (exposure wavelength) of exposure light to be used becomes shorter and the numerical aperture (NA) of a projection optical system is larger, whereas on the contrary, its depth of focus becomes narrower. As countermeasures for the narrowing depth of focus that accompanies such improvement of resolution, various methods for substantially widening the depth of focus without reducing resolution have conventionally been suggested (refer to Patent document 1, for example), such as a phase shift reticle method, a modified illumination method, a double exposure method, and a method combining these methods. However, because it is presumed that the exposure wavelength will be even shorter in the future in order to cope with higher integration of integrated circuits, new countermeasures for the narrowing depth of focus that accompanies the shorter wavelength will further be necessary.

From such a background, an immersion method has been recently suggested as a method of substantially shortening the exposure wavelength and increasing (widening) the depth of focus than in the air. In the immersion method, resolution is improved by filling a space between the bottom surface of the projection optical system and a wafer surface with liquid such as water and organic solvent, and using the fact that the actual wavelength of the exposure light in the liquid becomes 1/n times than in the air (n denotes the refractive index of liquid, which is normally about 1.2 to 1.6). Also, in the immersion method, the depth of focus is expanded by n times when compared to a projection optical system that can obtain the same resolution without using the immersion method (assuming that manufacturing such a projection optical system is possible), that is, the depth of focus is expanded by n times than in the air (refer to Patent document 2, for example).

As is described, although an exposure apparatus that realizes high resolution and wide depth of focus by substantially shortening the wavelength of exposure light, such as the exposure apparatus using the immersion method, can be referred to as the most suitable exposure apparatus from the viewpoint of exposure accuracy, such an exposure apparatus generally tends to require a relatively longer time for exposure. Especially in the case where double exposure referred to above is to be performed by the exposure apparatus that uses the immersion method, there is a fear of throughput being reduced.

Patent document 1: International Publication No. 99/65066 pamphlet

Patent document 2: International Publication No. 99/49504 pamphlet

### DISCLOSURE OF INVENTION

### Means for Solving the Problems

The present invention has been created under the circumstances described above, and according to a first aspect of the present invention, there is provided a first exposure method in which a plurality of times of exposure is performed on a same photosensitive object wherein the substantial wavelength of an exposure light in a space between a projection optical system, which projects the exposure light on the photosensitive object, and the photosensitive object is different in at least one exposure in the plurality of times of exposure from another exposure.

In this description, “substantial wavelength of exposure light” will refer to the wavelength of exposure light when the light actually reaches the photosensitive object. Further, “photosensitive object” includes an object on which photosensitive agent is coated, and “a plurality of times of exposure is performed on a same photosensitive object” includes exposure of a plurality of times to the same layer of photosensitive agent, which is formed on an object.

With this method, when exposure a plurality of times to the same photosensitive object, in at least in one exposure out of the plurality of times of exposure, the substantial wavelength of exposure light in a space between the projection optical system, which projects the exposure light on the photosensitive object, and the photosensitive object is made to differ from the wavelength of the exposure light in the space in another exposure out of the plurality of times of exposure. Therefore, for example, in an exposure that requires a high resolution, the substantial exposure wavelength of the exposure light in the space between the projection optical system and the photosensitive object can be shortened, while in an exposure that does not require a resolution so high, the substantial wavelength of exposure light can be made longer to a certain level. Accordingly, in the case of performing exposure a plurality of times on the same photosensitive object, wavelength according to the required resolution can be adopted in each exposure, and as a result, exposure satisfying both high accuracy and high throughput can be achieved.

According to a second aspect of the present invention, there is provided a second exposure method in which a plurality of times of exposure is performed on a same photosensitive object, the method comprising: a process in which under a first exposure condition where a substantial wavelength of the exposure light in a space between an optical member and the photosensitive object is a first wavelength, the photosensitive object is exposed by the exposure light of the first wavelength, and a process in which under a second exposure condition where a substantial wavelength of the exposure light in a space between the optical member and the photosensitive object is a second wavelength different from the first wavelength, the photosensitive object is exposed by the exposure light of the second wavelength.

With this method, when performing exposure a plurality of times to the same photosensitive object, the exposure light exposes the photosensitive object under the first exposure condition where the substantial wavelength of the exposure light in a space between an optical member and the photosensitive object is the first wavelength, and the exposure light exposes the photosensitive object under the second exposure condition where the substantial wavelength of the exposure light in the space between the optical member and the photosensitive object is the second wavelength, which differs from the first wavelength. Therefore, for example, in the exposure that requires a high resolution, the substantial exposure wavelength of the exposure light in the space between the projection optical system and the photosensitive object is shortened, whereas in the exposure that does not require a high resolution so much, the substantial wavelength of the exposure light is made longer to a certain level. In other words, in the exposure that requires a high resolution, the exposure light exposes the photosensitive object under one exposure condition, in which the wavelength is shorter of the first wavelength and the second wavelength, and in the exposure that does not requires a high resolution so much, the exposure light exposes the photosensitive object under another exposure condition. Therefore, in the case of performing exposure a plurality of times to the same photosensitive object, the wavelength according to the required resolution can be adopted in each exposure, and as a result, exposure that satisfies both high accuracy and high throughput can be achieved.

According to a third aspect of the present invention, there is provided an exposure apparatus that performs a plurality of times of exposure on a same photosensitive object, the apparatus comprising: a stage that holds the photosensitive object; a projection optical system that projects an exposure light on the photosensitive object; an adjustment unit that adjusts a substantial wavelength of the exposure light in a space between the projection optical system and the photosensitive object; and a control unit that controls the adjustment unit when exposing the photosensitive object a plurality of times so that in at least one exposure of the plurality of times, the substantial wavelength of the exposure light in the space is different from the wavelength in another exposure.

With this apparatus, since it is equipped with the adjustment unit and the control unit, when performing exposure a plurality of times to the same photosensitive object, in at least one exposure, the substantial wavelength of the exposure light in the space between the projection optical system, which projects the exposure light on the photosensitive object, and the photosensitive object can be made to differ from the wavelength of the exposure light in the space in another exposure of the plurality of times of exposure. Therefore, for example, in an exposure that requires a high resolution, the substantial exposure wavelength of exposure light in the space between the projection optical system and the photosensitive object can be shortened, whereas in the exposure that does not require a high resolution so much, the substantial wavelength of the exposure light is made longer to a certain level. Accordingly, in the case of performing exposure a plurality of times to the same photosensitive object, the wavelength according to the required resolution can be adopted in each exposure, and as a result, exposure that satisfies both high accuracy and high throughput can be achieved.

According to a fourth aspect of the present invention, there is provided an exposure system that performs exposure on a same photosensitive object a plurality of times, the system comprising: a first exposure apparatus whose substantial wavelength of an exposure light in a space between a projection optical system, which projects the exposure light on the photosensitive object, and the photosensitive object is a predetermined length; and a second exposure apparatus whose substantial wavelength of an exposure light in a space between a projection optical system, which projects the exposure light on the photosensitive object, and the photosensitive object is longer than the predetermined length.

According to this system, because the system is equipped with the first and second exposure apparatus whose substantial wavelength of the exposure light in the space between the projection optical system and the photosensitive object differ from each other, in the case of performing exposure a plurality of times to the same photosensitive object using the first and second exposure apparatus, when a high resolution is required, exposure can be performed using the first exposure apparatus by shortening the substantial wavelength of the exposure light in the space between the projection optical system and the photosensitive object, while when the resolution required is not so high, exposure can be performed using the second exposure apparatus by making the substantial wavelength of the exposure light longer to a certain level. Accordingly, in the case of performing exposure a plurality of times to the same photosensitive object, a temporally advantageous exposure method according to the required resolution of each exposure can be adopted, and as a result, exposure that satisfies both high accuracy and high throughput can be achieved.

In a lithography process, by performing exposure a plurality of times to the same photosensitive object executing either one of the first and second exposure methods of the present invention, exposure with high accuracy and high throughput can be achieved, and as a result, the productivity of highly integrated devices can be improved. Therefore, the present invention, from another aspect, is a device manufacturing method including a lithography process, in which a photosensitive object is exposed a plurality of times.

Further, in the lithography process, by transferring a device pattern onto the photosensitive object by using the exposure apparatus of the present invention, exposure with high accuracy and high throughput can be achieved, and as a result, productivity of highly integrated devices can be improved. Similarly, in the lithography process, by transferring a device pattern on the photosensitive object by using the exposure system of the present invention, exposure with high accuracy and high throughput can be achieved, and as a result, the productivity of highly integrated devices can be improved. Therefore, from another aspect, the present invention can also be said to be a device manufacturing method including a lithography process, in which a device pattern is transferred onto a photosensitive object by using the exposure apparatus or the exposure system of the present invention.

### BRIEF DESCRIPTION OF THE DRAWINGS

FIG. 1 is a view schematically showing a configuration of a lithography system related to a first embodiment of the present invention.

FIG. 2 is a view schematically showing a configuration of an exposure apparatus related to the first embodiment of the present invention.

FIG. 3 is a perspective view showing a Z-tilt stage and a wafer holder.

FIG. 4 is a schematic plan view showing a liquid supply/drainage system.

FIG. 5 is a block diagram showing the main configuration of the control system of the exposure apparatus related to the first embodiment.

FIG. 6 is a view showing an example of a pattern formed on a wafer by double exposure.

FIG. 7A is a view showing an example of a reticle used in double exposure.

FIG. 7B is a view showing an example of another reticle used in double exposure.

FIG. 8 is a flowchart showing the process algorithm of a host computer system constituting an exposure system of the first embodiment.

FIG. 9 is a flowchart showing a process algorithm executed by a main controller of an exposure apparatus to which exposure is instructed according to instructions in step 207 in FIG. 8.

FIG. 10 is a flowchart showing a process algorithm executed by the main controller of the exposure apparatus to which exposure is instructed according to instructions in step 213 in FIG. 8.

FIG. 11 is a view schematically showing a configuration of an exposure apparatus related to a second embodiment of the present invention.

FIG. 12 is a schematic plan view showing an example of a reticle stage.

FIG. 13 is a plan view showing a stage unit related to the second embodiment.

FIG. 14 is a flowchart showing a process algorithm of an exposure operation in the exposure apparatus of the second embodiment.

FIG. 15 is a flowchart for explaining an embodiment of a device manufacturing method related to the present invention.

FIG. 16 is a flowchart showing the details of step 804 in FIG. 15.

### BEST MODE FOR CARRYING OUT THE INVENTION

### A FIRST EMBODIMENT

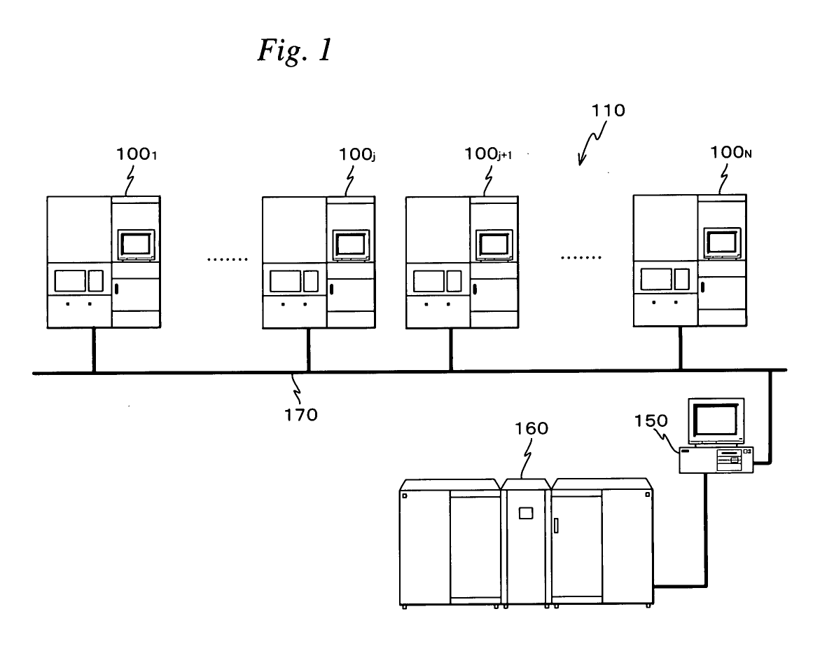

A first embodiment of the present invention will be described below, referring to FIGS. 1 to 10; however, the present invention is not limited to this.

FIG. 1 schematically shows the configuration of a lithography system 110 serving as an exposure system related to the first embodiment of the present invention. Lithography system 110 includes N units of exposure apparatus (100₁to 100_{N}), a terminal server 150, a host computer system 160 and the like. Of these parts, each exposure apparatus 100ᵢ (i=1, 2, . . . , j, j+1, . . . , N) and terminal server 150 connect to a local area network (LAN) 170, and the host computer system 160 connects to terminal server 150. Further, a communication path is secured between exposure apparatus (100₁ to 100_{N}) and host computer system (hereinafter, simply referred to as a “host”) 160, and communication between host 160 and exposure apparatus (100₁ to 100_{N}) is performed using the communication path.

Exposure apparatus (100₁ to 100_{N}) can each be a projection exposure apparatus by the step-and-repeat method, which is the so-called stepper, or a projection exposure apparatus by the step-and-scan method, that is, the scanning stepper (also called a scanner). In the description below, all the exposure apparatus (100₁ to 100_{N}) are to be scanning steppers for the sake of convenience.

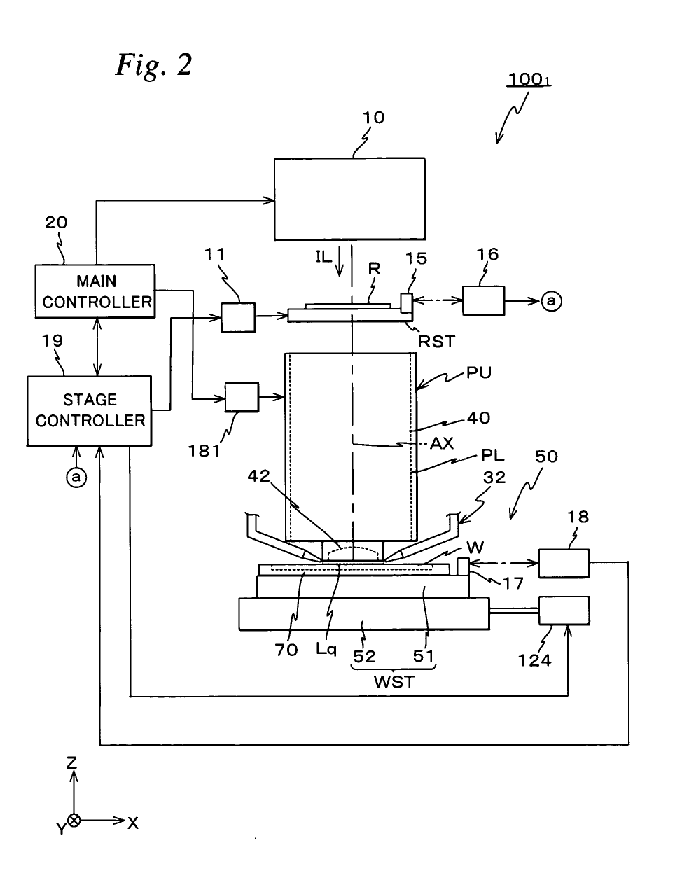

FIG. 2 shows a schematic configuration of an exposure apparatus 100₁, which represents exposure apparatus (100₁ to 100_{N}) in FIG. 1. Exposure apparatus 100₁ is equipped with an illumination system 10, a reticle stage RST that holds a reticle R, a projection unit PU, a stage unit 50 including a wafer stage WST on which a wafer W serving as a photosensitive object is mounted, a control system for these parts and the like.

As is disclosed in, for example, Kokai (Japanese Unexamined Patent Application Publication) No. 2001-313250 and its corresponding U.S. Patent Application Publication No. 2003/0025890 description or the like, illumination system 10 is configured including an illuminance uniformity optical system that includes a light source, an optical integrator or the like. Illumination system 10 also includes an illumination system aperture stop, a beam splitter, a relay lens, a variable ND filter, reticle blinds (a fixed reticle blind and a movable reticle blind) and the like (all of which are not shown). Under the control of a main controller 20, illumination system 10 illuminates a slit shaped illumination area (an area set by the reticle blind), which narrowly extends in an X-axis direction (the lateral direction in the page surface of FIG. 2) on reticle R where a circuit pattern or the like is drawn, by exposure light IL serving as an energy beam with virtually uniform illuminance. Herein, as an example, an ArF excimer laser beam (wavelength: 193 nm) is used as exposure light IL. As exposure light IL, it is also possible to use far ultraviolet light such as a KrF excimer laser beam (wavelength: 248 nm) or an emission line (such as a g-line or an i-line) in the ultraviolet region from an ultra high pressure mercury lamp. Further, as the optical integrator, a fly-eye lens, a rod integrator (an internal reflection integrator) or a diffractive optical element can be used. Illumination system 10 can have an arrangement similar to the illumination system disclosed in, for example, Kokai (Japanese Unexamined Patent Application Publication) No. 6-349701 and the corresponding U.S. Pat. No. 5,534,970 or the like. As long as the national laws in designated states or elected states, to which this international application is applied, permit, the above disclosures of the Kokai publications, the U.S. Patent application publication description, and the U.S. Patent are incorporated herein by reference.

The conditions of exposure light IL emitted from illumination system 10, that is, various illumination conditions, can be set by main controller 20.

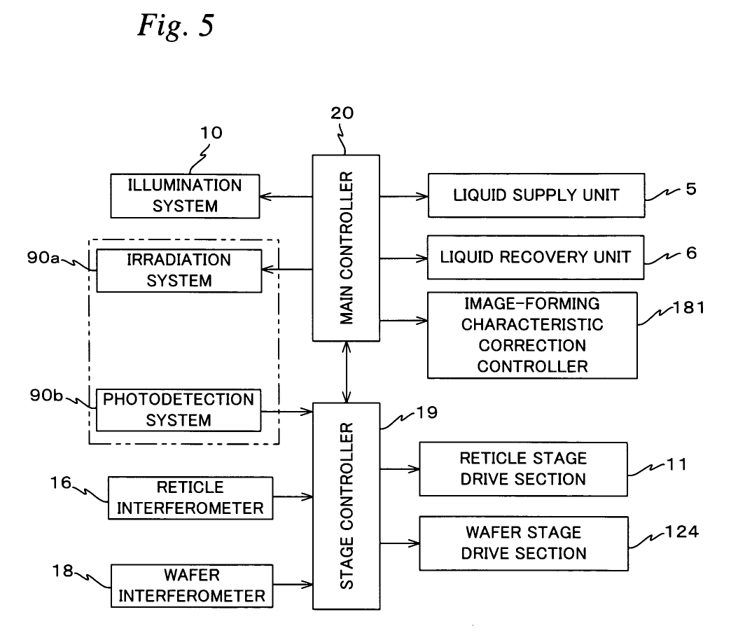

On reticle stage RST, reticle R is fixed, for example, by vacuum chucking. Reticle stage RST, for example, can be finely driven within an XY plane, which is vertical to the optical axis (matches the optical axis AX of a projection optical system PL (described later)) of illumination system 10, and also can be driven in a predetermined scanning direction (herein, it is a Y-axis direction, which is orthogonal to the page surface in FIG. 2) at a designated speed by a reticle stage drive section 11 (not shown in FIG. 2, refer to FIG. 5), which includes a linear motor or the like.

The position of reticle stage RST within a stage moving plane is constantly detected by a reticle laser interferometer (hereinafter, referred to as a “reticle interferometer”) 16 via a movable mirror 15 at a resolution of, for example, around 0.5 to 1 nm. Herein, actually, on reticle stage RST, a movable mirror having a reflection surface orthogonal to the Y-axis direction and a movable mirror having a reflection surface orthogonal to the X-axis direction are arranged, and corresponding to the movable mirrors a reticle Y-axis interferometer and a reticle X-axis interferometer are arranged; however, in FIG. 2, they are representatively shown as movable mirror 15 and reticle interferometer 16. Herein, one of the reticle Y-axis interferometer and the reticle X-axis interferometer, such as the reticle Y-axis interferometer, is a dual-axis interferometer having two measurement axes, and based on measurement values of the reticle Y-axis interferometer, rotation in a θz (rotation around a Z-axis) direction can be measured in addition to the position (Y position) of reticle stage RST in the Y-axis direction.

The positional information of reticle stage RST which is measured by reticle interferometer 16 is supplied to a stage controller 19 and to main controller 20 via stage controller 19. In response to instructions from main controller 20, stage controller 19 controls the drive of reticle stage RST via reticle stage drive section 11, based on the positional information of reticle stage RST.

Projection unit PU is disposed below reticle stage RST in FIG. 2. Projection unit PU includes a barrel 40 and a projection optical system PL made up of a plurality of optical elements that are held in barrel 40 at a predetermined positional relationship. As projection optical system PL, a both-side telecentric dioptric system made up of a plurality of lenses (lens elements) that share a common optical axis AX in the Z-axis direction, having a predetermined projection magnification (for example, ¼, ⅕ or ⅛) is used. Therefore, when the illumination area of reticle R is illuminated by exposure light IL from illumination system 10, by exposure light IL having passed reticle R, a reduced image of the circuit pattern (a reduced image of a part of the circuit pattern) of reticle R in the illumination area is formed on wafer W whose surface is coated with a resist (photosensitive agent), via the projection unit PU (projection optical system PL).

In exposure apparatus 100₁, since exposure is performed by the immersion method as in the description later on, the aperture on reticle R side becomes larger as the numerical aperture NA increases. Therefore, it becomes difficult for the dioptric system made up only by lenses to satisfy Petzval condition, which tends to lead to a larger projection optical system. To prevent the projection optical system from becoming larger, a catadioptric system that is configured including mirrors and lenses can be employed. Further, a reflection system that does not include a dioptric system can be employed as projection optical system PL.

Further, although it is not shown, a specific plurality of lenses out of the plurality of lenses constituting projection optical system PL is controlled by an image forming characteristic correction controller 181 (refer to FIG. 5) based on a command from main controller 20, and the optical properties (including image forming characteristics) of projection optical system PL, which are magnification, distortion, coma, curvature of image plane (including inclination of image plane) or the like, can be adjusted.

Further, in exposure apparatus 100₁, a liquid supply/drainage system 32 for locally supplying liquid to a space between a lens closest to the image plane side (close to wafer W side) constituting projection optical system PL, that is, a front lens (hereinafter, referred to as a “tip lens”) 42 and wafer W on wafer stage WST, or in other words, the space between tip lens 42 and wafer stage WST. The configuration or the like of the liquid supply/drainage system will be described later in the description.

Stage unit 50 is equipped with wafer stage WST, a wafer holder 70 arranged on wafer stage WST, a wafer stage drive section 124 that drives wafer stage WST, and the like. Wafer stage WST is arranged on a base (not shown) below projection optical system PL in FIG. 2, and is equipped with an XY stage 52, which is driven in an XY direction by a linear motor or the like (not shown) constituting wafer stage drive section 124, and a Z tilt stage 51 that is mounted on XY stage 52 and finely driven in the Z-axis direction and in an inclination direction with respect to the XY plane (the rotational direction around the X-axis (θx direction) and the rotational direction around the Y-axis (θy direction)) by a Z tilt drive mechanism (not shown) consisting wafer stage drive section 124. Wafer holder 70 that holds wafer W is mounted on Z tilt stage 51.

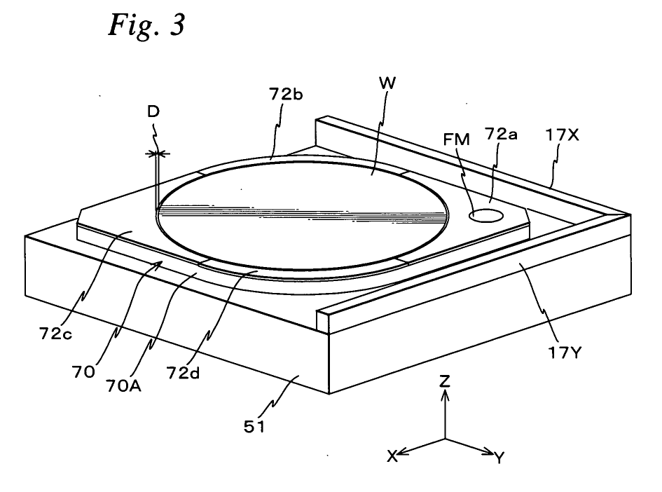

As is shown in the perspective view of FIG. 3, wafer holder 70 is equipped with a main body section 70A of a specified shape in which of the peripheral section of an area where wafer W is mounted (a circular area in the center), two corner sections located on a diagonal line of the square-shaped Z tilt stage 51 are severally protruded and two corner sections located on the other diagonal line form a quarter circle of a circle slightly larger than the circular area described above, and four auxiliary plates, 72a to 72d, disposed in the periphery of the area where wafer W is mounted so as to virtually overlap main body section 70A. The surface of auxiliary plates 72a to 72d should be virtually the same height as the surface of wafer W (the difference between both heights is 1 mm or less). Although auxiliary plates 72a to 72d are partially formed on wafer stage WST, they can also be formed to entirely cover wafer stage WST so as to make the upper surface of wafer stage WST virtually the same height (flush) In this case, the upper surface of movable mirrors 17X and 17Y can also be made virtually the same height as the auxiliary plates. The surface of auxiliary plates 72a to 72d does not necessarily have to be the same height as the surface of wafer W, and a difference in level may exist between the surface of auxiliary plates 72a to 72d and the surface of wafer W as long as liquid Lq can be maintained in a good condition on the image plane side of tip lens 42.

As is shown in FIG. 3, a gap D exists between each of the auxiliary plates 72a to 72d and wafer W, and the distance of gap D is set to be from 0.1 mm up to 1 mm. Further, a notch (a V-shaped cut) exists in a part of wafer W, but it is not shown because the dimension of the notch is also about 1 mm.

Further, a circular opening is formed on a part of auxiliary plate 72a, and a fiducial mark plate FM is fitted into the opening without making a gap. The surface of fiducial mark plate FM should be on the same surface (flush) as auxiliary plate 72a. On the surface of fiducial mark plate FM, various fiducial marks used for reticle alignment (described later), baseline measurement of an alignment system, or the like (all are not shown) are formed.

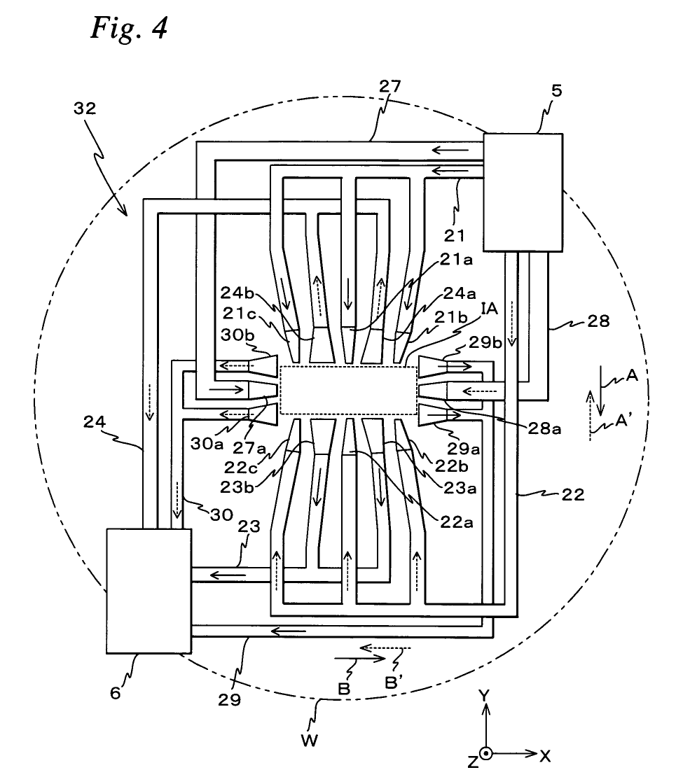

Returning to FIG. 2, XY stage 52 is constituted so that it can move not only in the scanning direction (the Y-axis direction) but also in the non-scanning direction (the X-axis direction) orthogonal to the scanning direction so that a plurality of shot areas of wafer W can be positioned on an exposure area IA (refer to FIG. 4) conjugate with the illumination area, and the stage performs a step-and-scan operation in which an operation of scanning exposure of each area on wafer W and an operation of moving to an acceleration starting position (scanning start position) for the exposure of the next shot (a moving operation between shot areas) are repeated.

The position of wafer stage WST within the XY plane (including the rotation around the Z-axis (θz rotation)) is constantly detected by a wafer laser interferometer (hereinafter, referred to as a “wafer interferometer”) 18 via a movable mirror 17 arranged on the upper surface of Z tilt stage 51 at a resolution of, for example, about 0.5 nm to 1 nm. Herein, on Z tilt stage 51 as is shown in FIG. 3, for example, a Y movable mirror 17Y having a reflection surface orthogonal to the scanning direction (Y-axis direction) and a movable mirror 17X having a reflection surface orthogonal to the non-scanning direction (X-axis direction) are actually arranged. And, corresponding to the movable mirrors, regarding the wafer interferometers, an X-axis interferometer that irradiates an interferometer beam vertically on X movable mirror 17X and a Y-axis interferometer that irradiates an interferometer beam vertically on Y movable mirror 17Y are arranged, however, FIG. 2 representatively shows them as movable mirror 17 and wafer interferometer 18. Meanwhile, both X-axis interferometer and Y-axis interferometer of wafer interferometer 18 are multi-axis interferometers having a plurality of measurement axes, and rotation (yawing (θz rotation being the rotation around Z-axis), pitching (θx rotation being the rotation around X-axis), and rolling (θy rotation being the rotation around Y-axis) can be measured by these interferometers in addition to the X and Y positions of wafer stage WST (Z tilt stage 51, more accurately). The edge surface of Z tilt stage 51 may be mirror-polished to form a reflection surface (corresponding to the reflection surface of movable mirrors 17X and 17Y). Further, the multi-axis interferometers may detect positional information related to the optical axis direction (the Z-axis direction) of projection unit PU, by irradiating a laser beam on a reflection surface provided on the frame on which projection unit PU is mounted (not shown), via a reflection surface arranged on Z tilt stage 51 at an inclination of 45°.

The positional information (or speed information) of wafer stage WST is supplied to stage controller 19 and to main controller 20 via controller 19. Stage controller 19 controls wafer stage WST via wafer stage drive section 124 based on the positional information (or speed information) of wafer stage WST in response to instructions from main controller 20.

Next, a description will be made on liquid supply/drainage system 32, referring to FIG. 4. Liquid supply/drainage system 32 is equipped with a liquid supply unit 5 serving as liquid supply mechanism, a liquid recovery unit 6, supply pipes 21, 22, 27, and 28 connecting to liquid supply unit 5, collection pipes 23, 24, 29, and 30 connecting to liquid recovery unit 6, and the like.

Liquid supply unit 5 is constituted by including a liquid tank, a compression pump, a temperature control unit, a plurality of valves for controlling the supply/stop of the liquid to supply pipes 21, 22, 27, and 28, and the like. As the valves referred to above, flow control valves are preferably used so that not only the supply/stop of the liquid but also the flow can be adjusted. The temperature control unit adjusts the temperature of the liquid within the liquid tank so that the temperature of the liquid is about the same level as the temperature within the chamber (not shown) where the exposure apparatus main body composed of projection unit PU and the like are housed.

One end of supply pipe 21 connects to liquid supply unit 5. The other end branches into three sections where on each end, supply nozzles 21a, 21b, and 21c consisting of a tapered nozzle are respectively formed (arranged). The tip of these supply nozzles 21a, 21b, and 21c are located in the vicinity of tip lens 42 (refer to FIG. 2) previously described, and are arranged in the X-axis direction at a predetermined distance and also close to the +Y side of an exposure area IA (an area on the image plane conjugate with the illumination area on the slit previously described). The supply nozzles are arranged symmetrically, with supply nozzle 21a in the center and supply nozzles 21b and 21c on both sides.

One end of supply pipe 22 connects to liquid supply unit 5. The other end branches into three sections where on each end, supply nozzles 22a, 22b, and 22c consisting of a tapered nozzle are respectively formed (arranged). The tip of these supply nozzles 22a, 22b, and 22c are located in the vicinity of tip lens 42, and are arranged in the X-axis direction at a predetermined distance and also close to the −Y side of exposure area IA. In this case, supply nozzles 22a, 22b, and 22c are arranged facing supply nozzles 21a, 21b, and 21c, with exposure area IA in between.

One end of supply pipe 27 connects to liquid supply unit 5. The other end has a supply nozzle 27a consisting of a tapered nozzle formed (arranged). The tip of supply nozzle 27a is located in the vicinity of tip lens 42, and is arranged close to the −X side of exposure area IA.

One end of supply pipe 28 connects to liquid supply unit 5. The other end has a supply nozzle 28a consisting of a tapered nozzle formed (arranged). The tip of supply nozzle 28a is located in the vicinity of tip lens 42, and is arranged close to the +X side of exposure area IA and also faces supply nozzle 27a, with exposure area IA in between

Incidentally, the liquid tank, the compression pump, the temperature adjustment unit, the valves, and the like do not all have to be equipped in exposure apparatus 100₁, and at least a part of such parts may be substituted by the equipment available in the factory where exposure apparatus 100 is installed.

Liquid recovery unit 6 is composed of parts including a liquid tank and a suction pump, and a plurality of valves for controlling the recovery/stop of the liquid via recovery pipes 23, 24, 29, and 30, and the like. As the valves, flow control valves are preferably used corresponding to the valves used in the liquid supply unit 5.

One end of recovery pipe 23 connects to liquid recovery unit 6. The other end branches into two sections where on each end, recovery nozzles 23a and 23b consisting of a widened nozzle are respectively formed (arranged). In this case, recovery nozzles 23a and 23b are arranged alternately in between supply nozzles 22a to 22c. The tip of recovery nozzles 23a and 23b and the tip of supply nozzles 22a, 22b, and 22c are arranged substantially collinear on a line parallel to the X-axis.

One end of recovery pipe 24 connects to liquid recovery unit 6. The other end branches into two sections where on each end, recovery nozzles 24a and 24b consisting of a widened nozzle are respectively formed (arranged). In this case, recovery nozzles 24a and 24b are arranged alternately in between supply nozzles 21a to 21c and also face recovery nozzles 23a and 23b, with exposure area IA in between. The tip of recovery nozzles 24a and 24b and the tip of supply nozzles 21a, 21b, and 21c are arranged substantially collinear on a line parallel to the X-axis.

One end of recovery pipe 29 connects to liquid recovery unit 6. The other end branches into two sections where on each end, recovery nozzles 29a and 29b consisting of a widened nozzle are respectively formed (arranged). Recovery nozzles 29a and 29b are arranged with supply nozzle 28a in between. The tip of recovery nozzles 29a and 29b and the tip of supply nozzle 28a are arranged substantially collinear on a line parallel to the Y-axis.

One end of recovery pipe 30 connects to liquid recovery unit 6. The other end branches into two sections where on each end, recovery nozzles 30a and 30b consisting of a widened nozzle are respectively formed (arranged). Recovery nozzles 30a and 30b are arranged with supply nozzle 27a in between, and also face recovery nozzles 29a and 29b, with exposure area IA in between. The tip of recovery nozzles 30a and 30b and the tip of supply nozzle 27a are arranged substantially collinear on a line parallel to the Y-axis.

Incidentally, the tank for recovering the liquid, the suction pump, the valves, and the like do not all have to be equipped in exposure apparatus 100₁, and at least a part of such parts may be substituted by the equipment available in the factory where exposure apparatus 100 is installed.

In the embodiment, as the liquid, ultra pure water (hereinafter, it will simply be referred to as ‘water’ besides the case when specifying is necessary) that transmits the ArF excimer laser beam (light with a wavelength of 193 nm) is to be used. Ultra pure water can be obtained in large quantities at a semiconductor manufacturing plant or the like, and it also has an advantage of having no adverse effect on the photoresist on the wafer or to the optical lenses. Further, ultra pure water has no adverse effect on the environment as well as an extremely low concentration of impurities, therefore, cleaning action on the surface of the wafer and the surface of tip lens 42 can be anticipated.

Refractive index n of water to ArF excimer laser beam is about 1.44. In the water, the spatial wavelength of exposure light IL is 193 nm×1/n, shorted to around 134 nm.

Liquid supply unit 5 and liquid recovery unit 6 both have a controller, and the controllers operate under the control of main controller 20 (refer to FIG. 5). For example, when wafer W is moved in a direction shown by a solid arrow A in FIG. 4 (−Y direction), according to instructions from main controller 20, the controller of liquid supply unit 5 opens the valve connected to supply pipe 21 to a predetermined degree and completely closes the other valves so as to supply the water in the space between tip lens 42 and wafer W toward the −Y direction via supply nozzles 21a to 21c arranged in supply pipe 21. Further, when the water is supplied, according to instructions from main controller 20, the controller of liquid recovery unit 6 opens the valve connected to recovery pipe 23 to a predetermined degree and completely closes the other valves so that the water is recovered inside liquid recovery unit 6 from the space between tip lens 42 and wafer W via recovery nozzles 23a and 23b. During the supply and recovery operations, main controller 20 gives orders to liquid supply unit 5 and liquid recovery unit 6 so that the amount of water supplied to the space between tip lens 42 and wafer W toward the −Y direction from supply nozzles 21a to 21c constantly equals the amount of water recovered via recovery nozzles 23a and 23b. Accordingly, a constant amount of water Lq is held in the space between tip lens 42 and wafer W.

Further, when wafer W is moved in a direction shown by a dotted arrow A′ in FIG. 4 (+Y direction), in a similar manner, according to instructions from main controller 20, the controller of liquid supply unit 5 opens the valve connected to supply pipe 22 to a predetermined degree and completely closes the other valves so as to supply the water in the space between tip lens 42 and wafer W toward the +Y direction via supply nozzles 22a to 22c arranged in supply pipe 22. Further, when the water is supplied, according to instructions from main controller 20, the controller of liquid recovery unit 6 opens the valve connected to recovery pipe 24 to a predetermined degree and completely closes the other valves so that the water is recovered inside liquid recovery unit 6 from the space between tip lens 42 and wafer W via recovery nozzles 24a and 24b.

As is described above, in exposure apparatus 100₁, a group of supply nozzles and a group of recovery nozzles that are grouped together is arranged on both one side and the other side of the Y-axis direction with exposure area IA in between. Therefore, in the case the wafer is moved in either the +Y direction or in the −Y direction, the space between wafer W and tip lens 42 continues to be filled stably with the water.

Further, because the water flows over wafer W, in the case foreign particles (including scattered particles from the resist) adhere on wafer W, the water can remove such foreign particles. Further, because liquid supply unit 5 supplies water whose temperature is adjusted to a predetermined temperature and the water is constantly circulated, even if illumination light IL is irradiated on wafer W on exposure, heat exchange is performed between the wafer and the water flowing over the wafer, which can suppress temperature increase of the wafer surface. Further, in exposure apparatus 100₁, because the water flows in the same direction as the moving direction of the wafer, the water that has absorbed the foreign particles or heat can be recovered without the liquid staying in exposure area IA directly under tip lens 42.

Further, when wafer W is moved in a direction shown by a solid arrow B in FIG. 4 (+X direction), in a similar manner, according to instructions from main controller 20, the controller of liquid supply unit 5 opens the valve connected to supply pipe 27 to a predetermined degree and completely closes the other valves so as to supply the water in the space between tip lens 42 and wafer W toward the +X direction via supply nozzle 27a arranged in supply pipe 27. Further, when the water is supplied, according to instructions from main controller 20, the controller of liquid recovery unit 6 opens the valve connected to recovery pipe 29 to a predetermined degree and completely closes the other valves so that the water is recovered inside liquid recovery unit 6 from the space between tip lens 42 and wafer W via recovery nozzles 29a and 29b.

Further, when wafer W is moved in a direction shown by a dotted arrow B′ in FIG. 4 (−X direction), in a similar manner, according to instructions from main controller 20, the controller of liquid supply unit 5 opens the valve connected to supply pipe 28 to a predetermined degree and completely closes the other valves so as to supply the water in the space between tip lens 42 and wafer W toward the −X direction via supply nozzle 28a arranged in supply pipe 28. Further, when the water is supplied, according to instructions from main controller 20, the controller of liquid recovery unit 6 opens the valve connected to recovery pipe 30 to a predetermined degree and completely closes the other valves so that the water is recovered inside liquid recovery unit 6 from the space between tip lens 42 and wafer W via recovery nozzles 30a and 30b.

In the manner described above, as in the case of moving wafer W in the Y-axis direction, in the case of moving the wafer in either the +X direction or the −X direction, the space between wafer W and tip lens 42 is also filled stably with the water.

In the description above, the case has been described in which the water is held in the space between wafer W and tip lens 42. However, as is previously described, because the surface of wafer W and the surface of wafer holder 70 are substantially flush, even in the case wafer holder 70 is located at a position corresponding to exposure area IA directly under projection unit PU, water Lq is held in the space between tip lens 42 and wafer holder 70, or in other words, auxiliary plates 72a to 72d previously described, as in the description above. Further, during the stepping operation, in the case water Lq can be held in the space between wafer W and tip lens 42, the water supply and recovery can be stopped.

In addition to the nozzles that supply and recover the water from the X-axis direction or the Y-axis direction, for example, nozzles that supply and recover the water from an oblique direction can also be arranged.

Further, liquid supply/drainage system 32 can have any arrangement as long as it can fill liquid between the optical member (tip lens) 42 constituting projection optical system PL at the bottom end. For example, the immersion mechanism disclosed in the Pamphlet of International Publication Number 2004/053955 and the immersion mechanism disclosed in European Patent Publication No. 1420298 can be also applied to the exposure apparatus of this embodiment.

In exposure apparatus 100₁ of the embodiment, in the holding member that holds projection unit PU (not shown), a multiple point focal position detection system based on an oblique method consisting of an irradiation system 90a (not shown in FIG. 2, refer to FIG. 5) and a photodetection system 90b (not shown in FIG. 2, refer to FIG. 5), similar to the one disclosed in, for example, Kokai (Japanese Patent Unexamined Application Publication) No. 6-283403 and the corresponding U.S. Pat. No. 5,448,332, is further arranged.

Defocus signals, which are an output of photodetection system 90b of focal position detection system (90a, 90b), are supplied to main controller 20. On scanning exposure (to be described later) or the like, main controller 20 computes the Z position of the wafer surface and the θx and θy rotations based on defocus signals such as the S-curve signal from photodetection system 90b, and controls the movement of wafer stage WST in the Z-axis direction and the inclination in a two-dimensional direction (that is, rotation in the θx and θy direction) via wafer stage drive section 124 so that the difference between the Z position of the wafer surface and the θx and θy rotations that have been calculated and their target values become zero, or in other words, defocus equals zero. And, by such control, main controller 20 performs auto-focusing (automatic focusing) and auto-leveling in which the imaging plane of projection optical system PL and the surface of the wafer are made to substantially coincide with each other within the irradiation area (the area optically conjugate with the illumination area described earlier) of illumination light IL. As long as the national laws in designated states or elected states, to which this international application is applied, permit, the above disclosures of Kokai (Japanese Patent Unexamined Application Publication) No. 6-283403 and the corresponding U.S. Patent are incorporated herein by reference.

FIG. 5 shows a main arrangement of a control system of exposure apparatus 100₁ of the embodiment. The control system is mainly composed of main controller 20, which is made up of a microcomputer (or a workstation) or the like having overall control over the entire apparatus, and of stage controller 19, which operates under the control of main controller 20.

In the first embodiment, main controller 20 is connected to a LAN 170 (refer to FIG. 1). More specifically, communication is performed between host 160 of FIG. 1 and main controller 20. Further, main controller 20 also controls a coater/developer (not shown) (hereinafter, referred to as a “C/D”) that is arranged along with exposure apparatus 100₁. C/D also includes a bake unit that performs post-exposure bake (PEB). As the bake unit, a unit by a resistance heating method, an infrared heating method or the like can be used. The PEB is performed for the purpose of accelerating catalytic reaction of chemically amplified resist after exposure.

In this lithography system 110, other exposure apparatus 100₂, 100₃, up to l00j are to be exposure apparatus that have a configuration similar to exposure apparatus 100₁, with each exposure apparatus having a C/D arranged, and the exposure apparatus are to perform exposure by the immersion method in the same manner as exposure apparatus 100₁. However, exposure apparatus 100ⱼ₊₁, 100ⱼ₊₂, up to 100_{N} are different from exposure apparatus 100₁ on the point that the apparatus are not equipped with liquid supply/drainage system 32, and the apparatus are designed to perform normal exposure (the so-called dry exposure) instead of immersion exposure. Further, in this lithography system 110, the number of exposure apparatus 100₁, 100₃, up to l00ⱼ that perform immersion exposure is to be larger than the number of exposure apparatus l00ⱼ₊₁, 100ⱼ₊₂, up to 100_{N} that do not perform immersion exposure. This is because the exposure time of the exposure apparatus performing immersion exposure tends to be longer than that of the exposure apparatus that does not perform immersion exposure, and in the case of performing overlay exposure, multiple exposure or the like in lithography system 110, downtime or the like of each exposure apparatus l00ᵢ can be made shorter when scheduling the process in the case the number of exposure apparatus performing immersion exposure is larger, which is considered to be convenient from the viewpoint of throughput.

Returning to FIG. 1, each exposure apparatus l00ᵢ (its main controller 20) communicates with host 160 via LAN 170 and terminal server 150, and executes various control operations in response to instructions from host 160.

Terminal server 150 is constituted as a gateway processor for absorbing a difference between the communication protocol of LAN 170 and the communication protocol of host 160. The function of terminal server 150 makes communication possible between host 160 and exposure apparatus 100₁ to 100_{N} connecting to the LAN 170.

Host 160 is a manufacturing execution system (MES) configured including a large-sized computer. Herein, the MES is a system that totally controls and analyzes the process, the equipment, the conditions, and the operation data of each product produced in a production line by a computer, and supports a more efficient production such as quality improvement, yield improvement and reduction of work error. Host 160 may be a system other than the MES, and for example, a computer may be used solely for this purpose.

Although both a bus LAN and a ring LAN can be employed as LAN 170, the first embodiment uses a bus LAN of a carrier sense media access with collision detection (CSMA/CD) method by the IEEE802 standard.

Next, an exposure operation of wafers in one lot in exposure system 110 related to the first embodiment will be described. The number of wafers in one lot in this case is set, based on the time in which the performance of the photosensitive agent (such as chemically amplified resist) coated on the surface of each wafer by the coater in the C/D of exposure apparatus 100₁ can be maintained. More specifically, the number of wafers in one lot is set so that the time until all the operations (including carriage operation) from coating the photosensitive agent on a wafer to developing the wafer are completed does not exceed the time in which the performance of the photosensitive agent can be maintained. In the first embodiment, the number of wafers in one lot is to be 25.

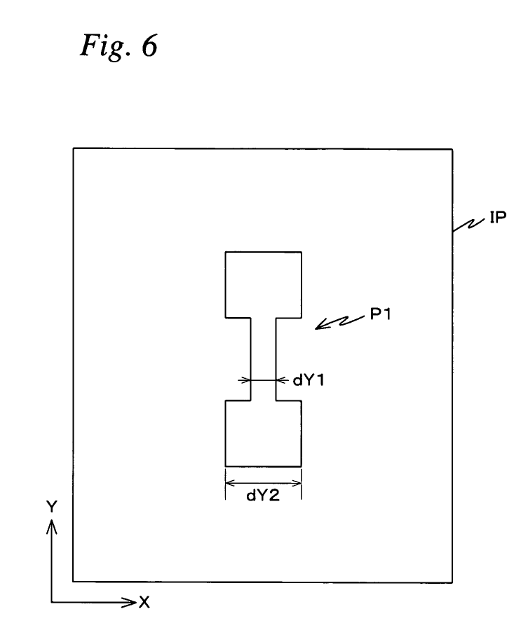

In the description below, as a specific example, a case will be described where a circuit pattern IP including a gate pattern P1 shown in FIG. 6 is transferred and formed by an exposure operation in lithography system 110 related to the first embodiment. As is shown in FIG. 6, gate pattern P1 is an isolated line that consists of a narrow line pattern (width: dY1) elongated in the Y-axis direction and wider overlay patterns (width: dY2) that are formed on both ends of the narrow line pattern. FIG. 6 shows gate pattern P1 in an enlarged size in circuit pattern IP and other patterns (wiring patterns, for example) are omitted.

Width dY1 of the narrow line pattern should be a width around the resolution limit of projection optical system PL of exposure apparatus 100ⱼ₊₁ or the like, which does not perform immersion exposure, or a width slightly narrower than the resolution limit. For example, when the exposure wavelength in exposure apparatus 100ⱼ₊₁ is λ and the numerical aperture of projection optical system PL is NA, the resolution limit of projection optical system PL virtually becomes 1·λ/NA using a predetermined process factor k1, therefore, width dY1 of the narrow line pattern should be around 1·λ/NA or a width slightly narrower. On the other hand, width dY2 of the overlay patterns in the X-axis direction is set to around 1.5 times wider than the resolution limit.

The narrow line pattern section of gate pattern P1 is, for example, a pattern that becomes the gate electrode of a field effect transistor. On the actual device, more than several tens of millions of such gate patterns are formed. The finer the gate electrodes are formed and the more uniform the line widths are in all areas of the device, the operation of the electronic device improves in speed.

In order to form such a gate pattern P1 on wafer W, for example, a positive resist is coated on wafer W, then a reticle having a light shield pattern that is enlarged into a similar shape is made, and its reduced image can be transferred onto wafer W by exposure apparatus 100ⱼ₊₁ or the like; however, in exposure apparatus 100ⱼ₊₁ or the like, it is difficult to expose a pattern image whose pattern is narrower than the resolution limit of the apparatus with high precision while maintaining an appropriate depth of focus.

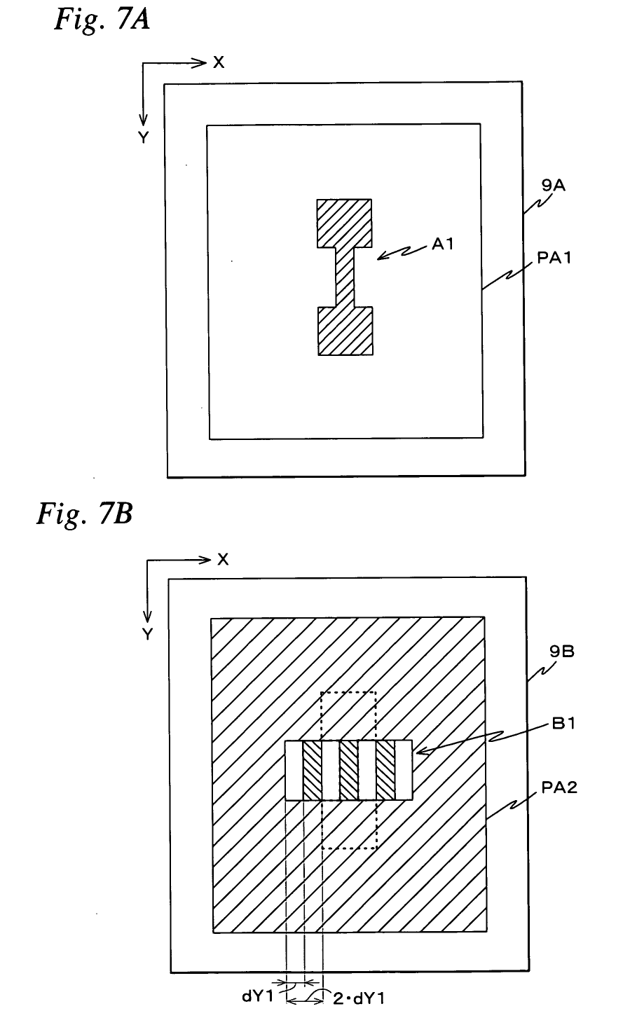

Therefore, in the first embodiment, two reticles 9A and 9B as is shown in FIGS. 7A and 7B are prepared, based on circuit pattern IP that is to be formed. The size of the actual reticle pattern is a value obtained by multiplying 1/β to the pattern size on wafer W; however, in the description below, for the sake of convenience, the size of each section of the reticle pattern is shown in a value converted into the size on wafer W. FIGS. 7A and 7B are views showing the pattern surface of reticles 9A and 9B, and are views where each reticle is seen from the −Z side when reticles 9A and 9B are mounted on reticle stage RST.

As is shown in FIG. 7A, a pattern area PA1 is formed on reticle 9A. On pattern area PA1, a light shield pattern Al that consists of a light shield film of a similar shape to gate pattern P1 shown in FIG. 6 (more accurately, a pattern multiplied by 1/β) is formed. In this case, the width of the section corresponding to the overlay patterns in light shield pattern A1 is the same as the width of the patterns for overlay, but the width of the section corresponding to the narrow line pattern is set to a width same as or wider than the width of the narrow line pattern. This makes it possible to prevent the line width of the narrow line pattern from becoming narrower than a desired width when exposing an image near the resolution limit.

As is shown in FIG. 7B, a pattern area PA2 is formed on reticle 9B. In pattern area PA2, a line-and-space (hereinafter, shortened to “L/S”) pattern B1 whose arrangement direction is in the X-axis direction is formed on a position corresponding to the narrow line pattern of gate pattern P1 shown in FIG. 6. FIG. 7B shows an area corresponding to gate pattern P1 shown in FIG. 6 in a dotted line. As is shown in FIG. 7B, L/S pattern B1 is a pattern in which four transmission patterns having the width of dY1 are arranged in the pitch of about 2·dY1 in the X-axis direction (that is, the direction orthogonal to the longitudinal direction of gate pattern P1) so that the patterns sandwich (are in contact with) an area corresponding to the narrow line pattern in gate pattern A1 shown in FIG. 7A. Areas between the transmission patterns are a light attenuation type (halftone type) phase shift area in which the phase of transmission light is shifted by 180° degrees with respect to the transmission pattern and transmittance is set to about 3% to 10%. It is a matter of course that the light attenuation type phase shift areas may also be a full light shield pattern. Further, the number of the transmission patterns of L/S pattern B1 is not limited to four, and it can be any number.

Meanwhile, in the first embodiment, the pattern corresponding to the gate pattern was the light shield pattern shown in FIG. 7A because the positive resist was used, but it is needless to say that when a negative resist is used, the pattern corresponding to the gate pattern should be a transmission pattern.

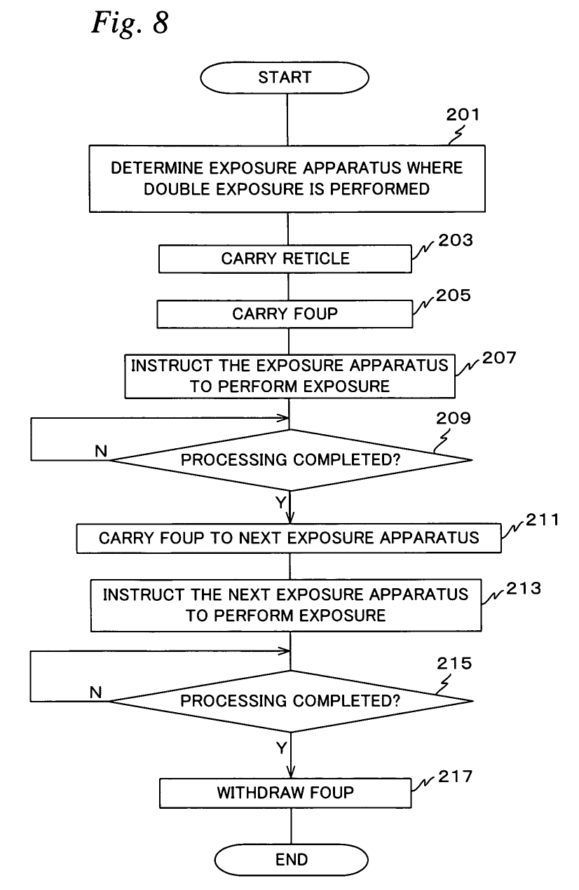

FIG. 8 shows the flowchart showing the process algorithm of host 160 when double exposure of the wafers in one lot is performed, using reticle 9A and reticle 9B. As a premise, exposure of 1 layer or more is to be performed on wafer W subject to exposure, and the process of this double exposure should be called a “current process”. The process algorithm of host 160 shown in the flowchart of FIG. 8 starts when the preparation of the exposure process corresponding to a process program for processing wafer W in the lot has begun.

First, in step 201 in FIG. 8, host 160 decides the exposure apparatus that expose wafer W in the one lot out of exposure apparatus 100₁ to 100_{N}. The exposure of the current process is double exposure, using reticle 9A and reticle 9B. In lithography system 110, although double exposure can be performed with one exposure apparatus, in the first embodiment, double exposure will be performed using two exposure apparatus. This case is advantageous from the viewpoint of throughput because operations such as exchanging the reticle when using one exposure apparatus can be omitted. Further, in this case, for one apparatus, an exposure apparatus performing immersion exposure is to be selected, and for the remaining apparatus, an exposure apparatus that does not perform immersion exposure is to be selected. In this case, for the exposure apparatus that does not perform immersion exposure, exposure apparatus 100ⱼ₊₁ is to be selected, and as for the exposure apparatus that performs immersion exposure, exposure apparatus 100₁ is to be selected. The configuration of exposure apparatus l00ⱼ₊₁ is the same as the configuration of exposure apparatus 100₁ shown in FIG. 2, except for liquid supply/drainage system 32, which is not provided in exposure apparatus 100ⱼ₊₁.

In the next step, step 203, host 160 instructs a carrier system (not shown) to carry the reticles. Accordingly, the carrier system (not shown) in the factory carries reticle 9A to exposure apparatus 100ⱼ₊₁ and also carries reticle 9B to exposure apparatus 100₁. The reticles carried to each of the exposure apparatus are transported by a reticle carrier system (not shown), and are respectively loaded on reticle stage RST in exposure apparatus 100₁ and on reticle stage RST in exposure apparatus 100ⱼ₊₁, in a state aligned (pre-alignment) with high precision.

In the next step, step 205, host 160 carries wafer W in the one lot, which are subject to exposure, to exposure apparatus 100ⱼ₊₁. Wafer W in the one lot subject to exposure this time is stored in a front opening unified pod (hereinafter, abbreviated to a “FOUP”) . The FOUP is set at a predetermined position after it is carried to exposure apparatus 100ⱼ₊₁ by a FOUP carrier unit (not shown). This setting allows the opening section of the FOUP to connect with the opening of a carrier system chamber (not shown) of exposure apparatus 100ⱼ₊₁ when the door of the FOUP is open, and wafer W can be taken out into exposure apparatus 100ⱼ₊₁.

In the next step, step 207, host 160 instructs the exposure of wafer W to exposure apparatus l00ⱼ₊₁. Accordingly, exposure in exposure apparatus 100ⱼ₊₁ begins. In the next step, step 209, the host waits until a process end notification is sent from exposure apparatus 100ⱼ₊₁.

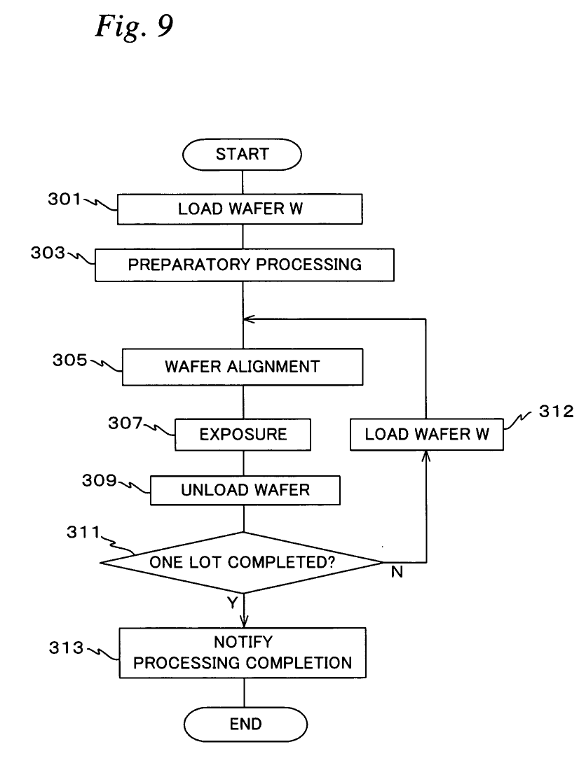

FIG. 9 shows a flowchart showing a process algorithm executed by main controller 20 when performing an exposure operation in exposure apparatusⱼ₊₁. As is shown in FIG. 9, first of all, the first (the beginning of the lot) wafer W in the lot is loaded in step 301. Resist coating has been completed to wafer W by a coater in a C/D (not shown) prior to the loading, and wafer W is carried by a carrier system (not shown), and then is delivered to wafer holder 70 on wafer stage WST after the pre-alignment or the like is performed. Prior to the loading, wafer W has been taken out from the FOUP by a carrier system (not shown), carried to the coater of the C/D in exposure apparatus 100ⱼ₊₁, and is coated on the surface by the coater with, for example, a positive chemically amplified resist. The chemically amplified resist is made of a base resin, a photo acid generator (PAG) and the like, and furthermore, some resist contains a dissolution inhibitor or a crosslinking agent. The resist coating process by the coater is to be performed to wafer W in the FOUP asynchronously, independent from the exposure operation in the flow chart, in the exposing order.

In the next step, step 303, a preparatory process such as reticle alignment using a reticle alignment system (not shown), fiducial mark plate FM described above and the like, and baseline measurement using an alignment system (not shown) or the like is performed.

In the next step, step 305, wafer alignment such as EGA (Enhanced Global Alignment) whose details are disclosed in, for example, Kokai (Japanese Unexamined Patent Application Publication) No. 61-44429 and the corresponding U.S. Pat. No. 4,780,617 or the like, is performed. As long as the national laws in designated states or elected states, to which this international application is applied, permit, the above disclosures of the Kokai publication and the U.S. Patent are incorporated herein by reference.

In the next step, step 307, in response to instructions from main controller 20, stage controller 19 performs scanning exposure of each shot area by controlling reticle stage drive section 11 and wafer stage drive section 124, based on the results of the wafer alignment while monitoring the measurement values of wafer interferometer 18 and reticle interferometer 16 described above. Main controller 20 controls the illumination operation by illumination system 10 in accordance with the control operation of stage controller 19 described above, as in a typical scanner.

During the scanning exposure of each shot area, stage controller 19 performs synchronous control so that a moving velocity Vr of reticle stage RST in the Y-axis direction and a moving velocity Vw of wafer stage WST in the Y-axis direction are maintained at a velocity ratio according to projection magnification β of projection optical system PL. By this control, the pattern of reticle 9A (light shield pattern A1 as a representative) is sequentially reduced and transferred onto each shot area on wafer W via projection optical system PL.

By this exposure operation, in the area of wafer W exposed by exposure light IL, acid is generated from the photo acid generator contained within the positive chemically amplified resist that is coated on the area. More specifically, on wafer W, acid is only generated from the photo acid generator contained within the resist of an area besides the area corresponding to the light shield pattern represented by light shield pattern A1, and at this point, the resist of the area (area other than the light shield pattern) that was exposed by exposure light IL has not become soluble yet.

In the next step, step 309, wafer W is unloaded. Accordingly, wafer W on wafer stage WST that has undergone exposure is unloaded, and is returned to the FOUP by the carrier system (not shown).

In the next step, step 311, the decision is made whether or not exposure of the wafers in one lot has been completed. In this case, since only exposure of the first wafer W has been completed, the decision here is denied, and the processing proceeds to step 312. In step 312, wafer W, which is the subject for the following exposure, is loaded on wafer stage WST. Then, the processing returns to step 305, after step 312 is completed.

Hereinafter, until the decision made in step 311 is affirmed, decision making of the conditions and the processing of step 305→step 307→step 309→step 311→step 312 are repeated. Accordingly, the pattern of pattern area PA1 of reticle 9A is severally transferred onto the shot areas of wafer W in the FOUP (in the lot) from the second wafer onward. Then, when exposure of the last wafer W in the lot ends and the decision in step 311 is affirmed, the processing proceeds to step 313.

In step 313, the main controller sends a process end notification is to host 160, and ends the process after step 313 is completed.

Returning to FIG. 8, when host 160 receives the process end notification described above, the process then proceeds to the next step, step 211 where instructions are given to the carrier system to carry the FOUP, which was set in exposure apparatus 100ⱼ₊₁, to exposure apparatus 100₁.

In the next step, step 213, host 160 instructs exposure apparatus 100₁ to expose wafer W. Accordingly, exposure in exposure apparatus 100₁ starts. By this instruction, main controller 20 of exposure apparatus 100₁ performs immersion exposure on all wafer Ws in the FOUP. Meanwhile, host 160 waits until a process end notification is sent from exposure apparatus 100₁ (step 215).

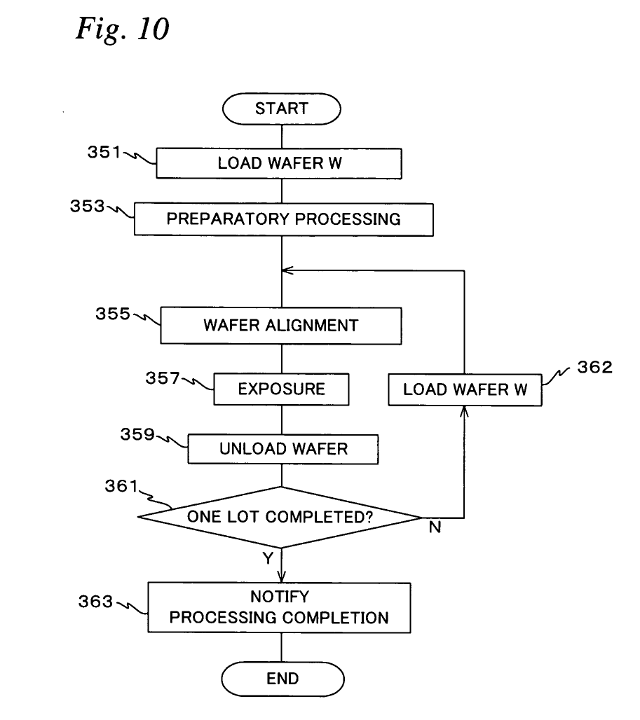

FIG. 10 shows a flowchart showing a process procedure executed by main controller 20 when the exposure operation is performed in exposure apparatus 100₁. As it is obvious when comparing FIGS. 10 and 9, the process procedure itself of main controller 20 in exposure apparatus 100₁ is virtually the same as the process procedure of main controller 20 in exposure apparatus 100ⱼ₊₁ shown in FIG. 9. However, the point where exposure apparatus 100₁ is equipped with liquid supply/drainage system 32, which performs the supply/drainage of the liquid during exposure, differs from the operation of exposure apparatus 100₁.

More specifically, first of all, in step 351 of FIG. 10, main controller 20 of exposure apparatus 100₁ loads the first (the beginning of the lot) wafer W in the FOUP on wafer stage WST in the same manner as step 301 described above. Next, before performing reticle alignment, which is one of the preparatory operations in step 353, main controller 20 controls the open/close of each valve of liquid supply unit 5 and liquid recovery unit 6 of liquid supply/drainage system 32, and starts to supply and recover the water to/from the space between tip lens 42 and wafer W. Consequently, a constant amount of water Lq is supplied to the space constantly in a stable state. That is, the preparatory process in step 353, the wafer alignment in step 355, and the exposure in step 357 are performed in a state where water Lq is held in the space under tip lens 42.

When performing the baseline measurement, which is one of the preparatory operations in step 353, and the wafer alignment in step 355, the space under tip lens 42 can be in a state where there is no liquid in the space. This is because the processing in baseline measurement and wafer alignment is performed using an off-axis alignment system (not shown) After finishing step 355 described above, main controller 20 starts the immersion exposure in step 357.

In the second exposure performed with exposure apparatus 100₁, the substantial wavelength of exposure light IL reaching wafer W (that is, the wavelength in the space between projection optical system PL (tip lens 42) and wafer W) is different from the wavelength in the first exposure performed with exposure apparatus 100ⱼ₊₁. More specifically, in exposure apparatus 100ⱼ₊₁, by dry exposure, exposure light IL, which is emitted from illumination system 10 and made to enter projection optical system PL, reaches wafer W while maintaining the wavelength (193 nm). However, in exposure apparatus 100₁, by immersion exposure, exposure light IL, which is emitted from illumination system 10 and made to enter projection optical system PL, reaches wafer W while the substantial wavelength of exposure light IL is converted into 134 nm by the water. In other words, in exposure apparatus 100₁, because immersion exposure is performed, the numerical aperture of the projection optical system can be larger than 1, which allows pattern projection with high resolution. Accordingly, the resolution of exposure apparatus 100₁ allows the pattern having width dY1 to be transferred with high precision. Further, since immersion exposure is performed in exposure apparatus 100₁, when the process factor and the numerical aperture NA of the projection optical system is the same, the depth of focus is enlarged by n times when compared with dry exposure in the air, and also from this sense, it can be said that the exposure is highly accurate.

After finishing step 357, main controller 20 stops supplying the liquid by liquid supply/drainage system 32, and performs unloading of wafer W in step 359 in a state where there is no liquid in the space under tip lens 42. Wafer W unloaded from wafer stage WST is returned to the FOUP by the carrier system (not shown). Next, in step 311, main controller 20 decides whether or not wafer W, which has been unloaded, is the last wafer in the one lot, and in the case the wafer is not the last wafer, moves on to step 362 where it loads wafer W, which is to be exposed next, on wafer stage WST in the state where there is no liquid in the space under tip lens 42.

Then, main controller 20 consecutively performs the loading of wafer in step 362, the wafer alignment in step 355, the immersion exposure in step 357, and the unloading of wafer in step 359 on each wafer W until the decision in step 361 is affirmed.

In the manner described above, the pattern on reticle 9B is transferred by the immersion method in exposure apparatus 100₁ onto each shot area of wafer W on which the pattern on reticle 9A was transferred. In exposure apparatus 100₁, wafer W unloaded from wafer stage WST is carried to the C/D by the carrier system (not shown) before it is returned to the FOUP, and is developed by a developer after PEB is applied by the bake unit, and then returned to the FOUP. Due to the PEB, in the resist on wafer W, for example, a dissolution restrainer is desorbed from the base resin, and alkali solubility appears on the exposed area and a latent image of the transferred pattern is formed on wafer W. Then, by the development, the area that has become soluble is removed, and the image of the transferred pattern (the pattern image shown in FIG. 6, for example) is formed on wafer W. When main controller 20 of exposure apparatus 100₁ confirms that wafer W have all been returned to the FOUP, then the decision in step 361 is affirmed, and the procedure proceeds to step 363 where a process end notification is sent to host 160. When host 160 receives the process end notification, the procedure proceeds to step 217 where the FOUP is withdrawn to a predetermined place by the FOUP carrier unit (not shown) to prepare for etching process in the current process, resist removal and exposure of the next layer, which ends the series of process.

As it is obvious from the description so far, in the first embodiment, by filling liquid Lq in the space between projection optical system PL and wafer W by using liquid supply/drainage system 32 that is controlled by main controller 20, the substantial wavelength of the exposure light in the optical path space is adjusted.

As is described above in detail, according to lithography system 110 related to the first embodiment, in the case of performing double exposure to the same resist layer on wafer W, in one exposure of the double exposure, the substantial wavelength of exposure light IL in the space between projection optical system PL, which projects exposure light IL on wafer W, and wafer W is made to differ from the wavelength of the exposure light in the space when the other exposure of the double exposure is performed. Therefore, for example, in the exposure that requires a high transfer accuracy, the substantial exposure wavelength of exposure light IL in the space between projection optical system PL and wafer W can be shortened, while in the exposure that does not necessarily require a high transfer accuracy, the substantial wavelength of exposure light IL can be made longer to a certain level. In the exposure where the substantial wavelength of exposure light IL is shortened, such as for example, in immersion exposure, the time required for exposure tends to be longer than regular exposure due to operations such as supplying the liquid. Accordingly, by employing the exposure method related to the first embodiment, a temporally advantageous exposure method according to the required resolution of each exposure can be employed, even in the case when exposure is performed a plurality of times, so that exposure satisfying both high accuracy and high throughput can be achieved. The total exposure time can be reduced, especially when compared with the case when immersion exposure is performed in both exposures of the double exposure.

Further, in the case of performing exposure by the immersion method using a chemically amplified resist as a photosensitive agent, there is a concern that the acid generated from the photo acid generator contained within the chemically amplified resist will dissolve into the liquid used in the immersion exposure. When such dissolution occurs, acid deactivation occurs, which reduces the acid concentration on the surface of the resist. This reduction causes insufficient desorption of the dissolution restrainer from the base resin, which may cause deterioration in a pattern profile. Further, there is also a concern that in the area on wafer W where the immersion time is different, an inconvenience may occur where the line width of a pattern, which should originally be the same, becomes uneven.

However, in the first embodiment, of the two exposures in the double exposure, the immersion exposure is performed in one. With this method, the time in which the chemically amplified resist coated on wafer W is immersed in the liquid for immersion exposure (pure water in the first embodiment) can be reduced than in the case where the immersion exposure is performed in both of the two exposures, so that the amount of acid dissolving into water, which is generated from the acid generator contained within the chemically amplified resist, can be reduced. As a result, the line width uniformity in different areas on wafer W can be improved, which makes exposure with high precision possible.

Meanwhile, when such acid dissolution is taken into consideration, in the case of performing exposure by the immersion method, it is desirable to reduce the time in which the surface of wafer W is immersed in liquid by setting the scanning speed to a high level. Further, it is desirable to select a chemically amplified resist that does not release acid immediately during an immersed state. Furthermore, as the liquid supplied from liquid supply/drainage system 32, liquid having lower solubility of acid than pure water may be used, or a protective film (top coat) may be coated on the resist.

In the first embodiment above, exposure apparatus 100ⱼ₊₁ was used in the first exposure and exposure apparatus 100₁ was used in the second exposure, however, any of the exposure apparatus 100ⱼ₊₂ to 100_{N} may be selected in the first exposure, and any of the exposure apparatus 100₂ to 100ⱼ may be selected in the second exposure.

Further, although the first exposure and the second exposure were performed per lot in the first embodiment, the double exposure may be performed per wafer. In such a case, it is advantageous because the time from exposure to PEB for each wafer can be reduced, by performing the second exposure immediately after performing the first exposure of each wafer, and then applying PEB to the wafer W. In the case of performing double exposure in different exposure apparatus, instead of carrying the wafers between the exposure apparatus by using the FOUP, a carrier system that carries wafer W one by one between the exposure apparatus can be arranged, and the carrier system can carry each wafer W.

Further, in lithography system 110 of the first embodiment, the number of exposure apparatus using the immersion method was larger than the number of exposure apparatus that do not use the immersion method, however, the present invention is not limited to this. The number of exposure apparatus using the immersion method may be smaller than the other exposure apparatus, and for example, it may be one.

Further, in the first embodiment described above, of the two exposures in the double exposure, the exposure performed immediately before PEB out is the immersion exposure. With this method, the time of wafer W in an immersed state from the immersed state until PEB is applied can be shortened, so that the time until PEB after exposing a finer pattern can be shortened and adverse effect such as contamination after exposure can be reduced. Further, inconveniences such as foreign particles adhering on wafer W due to the residual liquid on wafer W that could not be recovered by liquid recovery unit 6 drying up can be prevented. Of the two exposures in the double exposure, the first exposure can be the immersion exposure and the second exposure may be the exposure other than the immersion method. In this case, when compared with the case of performing the immersion exposure the second time after performing the first exposure (after acid generated on wafer W became soluble) as is described above, since the immersion exposure is performed on the first time, acid dissolution into the liquid (water) occurring on wafer W can be reduced.

Whether the immersion exposure should be performed the first time or the second time may be determined depending on various process conditions, such as emphasis is to be placed on reducing the time until PEB is applied after the immersion exposure (after exposure by exposure light having shorter actual wavelength) or emphasis is to be placed on acid dissolution during the immersion exposure.

Further, in the first embodiment above, exposure apparatus of a single stage type having one wafer stage were used, however, exposure apparatus of a double stage (twin stage) type can be included. Especially for exposure apparatus 100₁ or the like that performs immersion exposure, since the throughput improves when using the double stage type exposure apparatus, it is also desirable in preventing the acid from dissolving.

Further, in the embodiment above, by performing the exposure of one time of the double exposure a state where liquid was not filled in the space between the projection optical system (tip lens) and wafer W, and performing the exposure of the other time in a state where liquid was held in the space between the projection optical system (tip lens) and wafer W, the substantial wavelength of the exposure light in the space between the projection optical system (tip lens) and wafer W was made to differ between the first exposure and the other exposure. However, the immersion exposure may be executed in both exposures in the double exposure. More specifically, the exposure apparatus 100ⱼ₊₁ to 100_{N} can be exposure apparatus that perform the immersion exposure as in exposure apparatuses 100₁ to 100ⱼ. In this case, if pure water is used as the liquid in exposure apparatus 100₁ to 100ⱼ, then the liquid having a smaller refractive index than the refractive index of pure water (1.44) can be used in exposure apparatus 100ⱼ₊₁ to 100_{N}. On the contrary, if pure water is used as the liquid in exposure apparatus 100ⱼ₊₁ to 100_{N}, then exposure apparatus 100₁ to 100ⱼ can use liquid having a larger refractive index to the exposure light (ArF beam) than that of pure water, such as for example, isopropanol. In the manner described above, the substantial wavelength of exposure light IL reaching wafer W can be made to differ between exposure apparatus 100₁ to 100ⱼ and exposure apparatus 100ⱼ₊₁ to 100_{N}. In this case as well, because the resolution limit of exposure apparatus l00ⱼ₊₁ to 100_{N} is lower than that of exposure apparatus 100₁ to 100ⱼ), it is desirable to use exposure apparatus 100₁ to 100ⱼ when a finer pattern is to be transferred. Further, as the liquid, for example, other than isopropanol, liquid such as glycerol having a CH bond or an OH bond, liquid (organic solvent) such as hexane, heptane and decane, a combination of any two types or more of these liquids, liquid of pure water to which the liquids above are added (combined), liquid of pure water to which base such as H⁺, Cs⁺, K⁺, Cl⁻, SO₄²⁻ and PO₄²⁻ or acid is added (combined), or liquid of pure water to which fine particles such as Al oxide are added (combined) may be used, and liquid having a desired refractive index to the exposure light can be appropriately used. It goes without saying that the absorption coefficient of these liquids to the exposure light is small (high transmittance), and it is also desirable for the temperature dependence of optical properties of the liquid to be small. Further, a liquid that affects projection optical system PL and the resist coated on the surface of a substrate P only to a small extent, and has a small viscosity is preferable.

Further, in the first embodiment above, the ArF excimer laser beam (wavelength: 193 nm) was used as exposure light IL; however, the oscillation wavelength of each light source between the exposure apparatus may be different. For example, the light source of exposure apparatus 100ⱼ₊₁ may be a KrF excimer laser light source (oscillation wavelength: 248 nm) and the light source of exposure apparatus 100₁ may be an ArF excimer laser light source. In this case, the immersion exposure may be performed in both exposure apparatus, or the dry exposure may be performed in both exposure apparatus. As a matter of course, an exposure apparatus using the F2 laser beam or the i-line as the exposure light may be used, or the immersion exposure may be performed by one of the two exposure apparatus whose light sources have different oscillation wavelengths and the dry exposure may be executed by the other apparatus. The point is, when exposure is performed a plurality of times to the same wafer W (the same photosensitive layer) between a plurality of exposure apparatus, the substantial wavelength of the exposure light reaching wafer W in at least one of the exposures should be different from that of the other exposures.

Furthermore, in the first embodiment above, since the double exposure is performed using different exposure apparatus, in actual, distortion of an image caused by aberration or the like of projection optical system PL of exposure apparatus l00ᵢ becomes a problem. Therefore, in lithography system 110 of the first embodiment above, host 160 or the like can control information related to image distortion in exposure apparatus 100ᵢ, and the double exposure may be performed after the image distortion between exposure apparatus have been adjusted by the image forming characteristic correction controller 181 (refer to FIG. 5) in each exposure apparatus.

In the first embodiment above, lithography system 110 performed the double exposure to the same resist layer of wafer W by using reticles 9A and 9B, however, multiple exposure may also be performed as in triple exposure or more. For example, the gate pattern may be transferred by reticles 9A and 9B, and the wiring pattern may further be transferred using a reticle on which the wiring pattern is formed. More specifically, in the case of forming a circuit pattern including a fine pattern, the circuit pattern is to be divided into patterns that are fine and not so fine, and multiple exposure is to be performed with a plurality of reticles on which each pattern is formed. And, when a pattern, which is not so fine, is to be transferred, exposure is to be performed in a state where there is no liquid (exposure with the exposure light having the first wavelength), whereas, when a fine pattern is to be transferred, immersion exposure (exposure with the exposure light having the second wavelength virtually shorter than the first wavelength) is to be performed.

### A SECOND EMBODIMENT

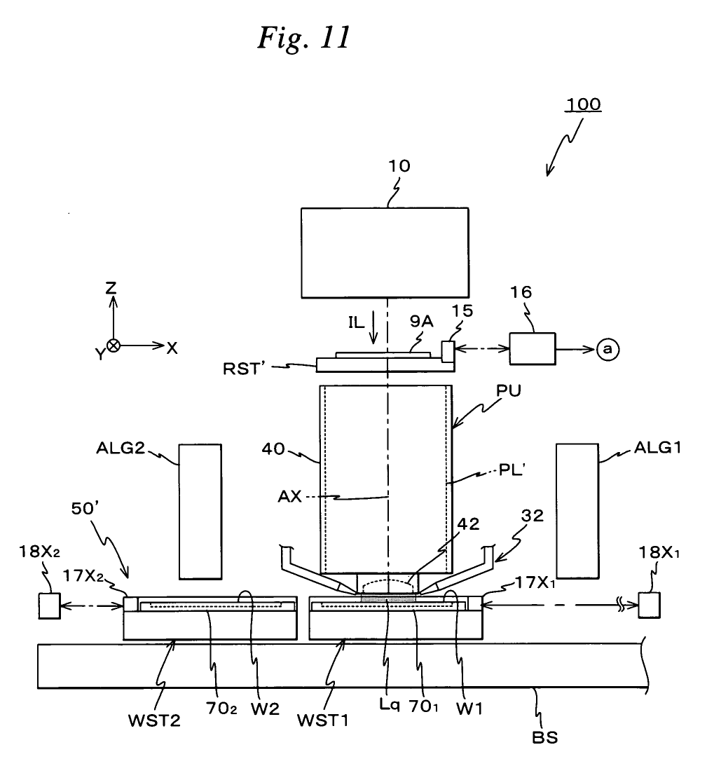

Next, a second embodiment of the present invention will be described, referring to FIGS. 11 to 14. In the first embodiment above, double exposure was performed using two different exposure apparatus, however, in the second embodiment, double exposure using reticle 9A and reticle 9B described above in one exposure apparatus will be performed.

FIG. 11 shows a schematic configuration of an exposure apparatus 100 related to the second embodiment of the present invention. Exposure apparatus 100 is a so-called step-and-scan exposure apparatus (scanning stepper). Exposure apparatus 100 is an exposure apparatus that can perform exposure by the immersion method similar to exposure apparatus 100₁ of the first embodiment, and is equipped with a liquid supply/drainage system 32. Exposure apparatus 100 is configured in a similar manner as exposure apparatus 100₁ except for the point that it is equipped with a projection optical system PL′ instead of projection optical system PL that can obtain a predetermined image forming characteristics by immersion exposure and dry exposure, a reticle stage RST′ instead of reticle stage RST, and a stage unit 50′ instead of stage unit 50, and furthermore, is equipped with two alignment systems ALG1 and ALG2 serving as an off-axis alignment system, and also is equipped with a wafer interferometer system (described later) instead of wafer interferometer 18, therefore, details on sections that are in common with exposure apparatus 100₁ will be omitted.

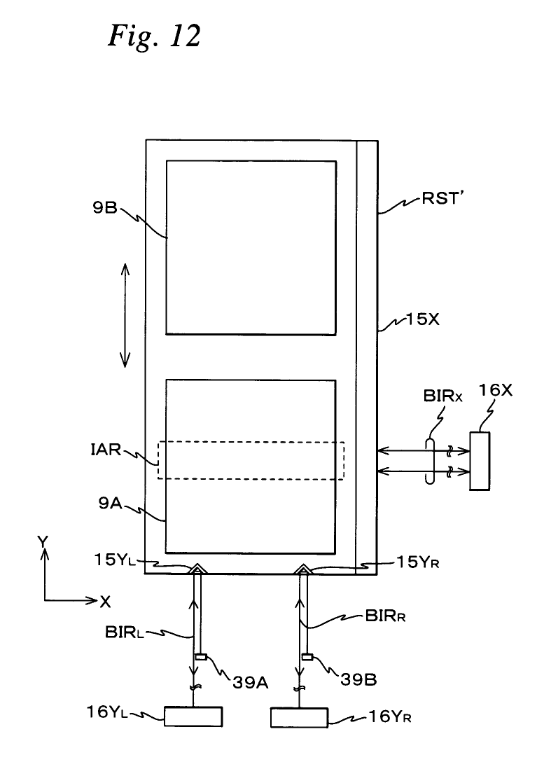

As is shown in FIG. 12, on reticle stage RST′, two reticles can be installed in series in the scanning direction (the Y-axis direction)’, which is different from reticle stage RST. FIG. 12 shows a state where reticles 9A and 9B are held on reticle stage RST′. Reticles 9A and 9B on reticle stage RST′ are selectively used, for example, when double exposure is performed, and both the reticles are configured so that they can be scanned synchronously with the wafer side. FIG. 12 shows a state where reticle 9A is selected, and on an area on reticle 9A corresponding to an irradiation area IAR shown by a dotted line, exposure light IL can be irradiated (or exposure light IL is irradiated).

On reticle stage RST′, on an edge section on one side in the X-axis direction of the stage, a movable mirror 15X constituting movable mirror 15 is arranged extending in the Y-axis direction, and on a surface on one side of moving mirror 15X in the X-axis direction, a reflection surface is formed by mirror-polishing. Toward the reflection surface of the movable mirror 15X, an interferometer beam is irradiated from an X-axis interferometer 16X in FIG. 11, which is shown by a measurement axis BIR_{X}. X-axis interferometer 16X obtains positional information or the like regarding the X-axis direction of reticle stage RST′ by receiving a reflected light from the mirror to measure relative displacement with respect to a datum surface.

On the other hand, on the other side of the Y-axis direction, which is the scanning direction of reticle stage RST′ (the lower side within the page surface of FIG. 12), a pair of retroreflectors 15Y_{L} and 15Y_{R} constituting movable mirror 15 is installed. Interferometer beams shown by measurement axes BIR_{L} and BIR_{R} are respectively irradiated from a pair of double pass interferometers 16Y_{L} and 16Y_{R} toward retroreflectors 15Y_{L} and 15Y_{R}. The beams are reflected by reflection mirrors 39A and 39B that are formed on the reflection surface on a reticle base plate (not shown), and the beams reflected by the mirror return the same optical paths and is severally received by double pass interferometers 16Y_{L} and 16Y_{R}, and then the relative displacement from a datum position (the reflection surface on the reticle base plate (not shown)) of each retroreflector 15Y_{L} and 15Y_{R} is measured. Then, the measurement values of the double pass interferometers 16Y_{L} and 16Y_{R} are supplied to stage controller 19, and the positional information in the Y-axis direction of reticle stage RST′ is measured based on their average value. The positional information in the Y-axis direction is used for computing the relative position between reticle stage RST′ and a wafer stage WST1 or a wafer stage WST2 (to be described later) and for synchronous control between reticles 9A and 9B and a wafer W1 (W2) in the scanning direction (the Y-axis direction) during scanning exposure based on the computation. Further, in exposure apparatus 100 related to the second embodiment, θz rotation of reticle stage RST′ is measured based on a difference between the measurement values of double pass interferometers 16Y_{L} and 16Y_{R}.

More specifically, in exposure apparatus 100, the X-axis interferometer 16X and the pair of the double pass interferometers 16Y_{L} and 16Y_{R} constitute reticle interferometer 16 (refer to FIG. 11) and the X-movable mirror 15X and the retroreflectors 15Y_{L} and 15Y_{R} constitute movable mirror 15 (refer to FIG. 11).

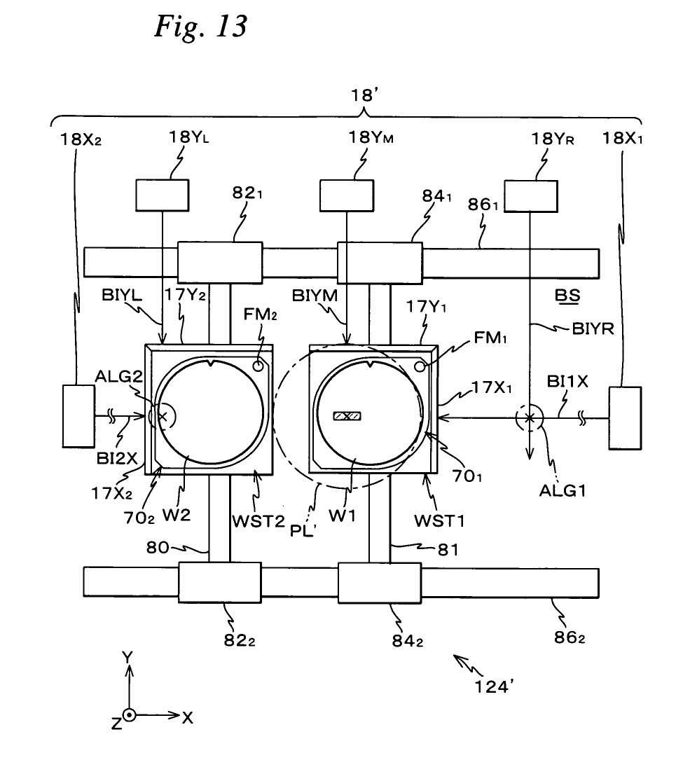

Next, stage unit 50′ will be described. As is shown in FIG. 11, stage unit 50′ is equipped with a base plate BS, wafer stages WST1 and WST2 disposed above base plate BS, an interferometer system including interferometers 18X₁ and 18X₂ or the like that severally measure the positions of wafer stages WST1 and WST2 (this system is called a “wafer interferometer system 18′”), and a wafer stage drive section 124′ (not shown in FIG. 11, refer to FIG. 13) that drives wafer stages WST1 and WST2.

Wafer stages WST1 and WST2 are configured independently drivable in a two-dimensional direction in the X-axis direction (the lateral direction within the page surface of FIG. 11) and the Y-axis direction (the orthogonal direction to the page surface of FIG. 11).

On base plate BS, as is shown in the planar view in FIG. 13, for example, a pair of X-axis linear guides 86₁ and 86₂ extending in X-axis directions, which consist of armature units, is arranged in the Y-axis direction at a predetermined distance. Above X-axis linear guides 86₁ and 86₂, for example, two sliders each 82₁ and 84₁, and 82₂ and 84₂, consisting of magnetic pole units are arranged in a state surrounding X-axis linear guides 86₁ and 86₂ in a non-contact manner. In other words, sliders 82₁ and 84₁ and X-axis linear guide 86₁ constitute a moving magnet type linear motor, and sliders 82₂ and 84₂ and X-axis linear guide 86₂ constitute a moving magnet type linear motor. In the following description, the motors will be appropriately called an X-axis linear motor 82₁, an X-axis linear motor 84₁, an X-axis linear motor 82₂, and an X-axis linear motor 84₂ by using the same reference numerals as sliders 82₁, 84₁, 82₂, and 84₂, which make up each mover.

The sliders constituting the two X-axis linear motors 82₁ and 82₂ out of the four X-axis linear motors 82₁, 84₁, 82₂, and 84₂ for example, are composed of armature units, and are fixed to both one end and the other end in the longitudinal direction of a Y-axis linear guide 80 extending in the Y-axis direction. Further, the sliders constituting the remaining two X-axis linear motors 84₁ and 84₂, for example, are composed of armature units, and are fixed to both one end and the other end in the longitudinal direction of a Y-axis linear guide 81 extending in the Y-axis direction. Therefore, Y-axis linear guides 80 and 81 are severally driven along the X-axis by each pair of X-axis linear motors 82₁ and 82₂ and X-axis linear motors 84₁ and 84₂.

Wafer stage WST1 is equipped with a magnetic pole unit (not shown), and the magnetic pole unit and Y-axis linear guide 81, which consists of the armature units, constitute a moving. magnet type Y-axis linear motor that drives wafer stage WST1 in the Y-axis direction. Further, wafer stage WST2 is equipped with a magnetic pole unit (not shown), and the magnetic pole unit and Y-axis linear guide 80 constitute a moving magnet type Y-axis linear motor that drives wafer stage WST2 in the Y-axis direction. In the description below, these Y-axis linear motors will be called a Y-axis linear motor 81 and a Y-axis linear motor 80 by using the same reference numerals as linear guides 81 and 80, which make up each stator.

In the second embodiment, X-axis linear motors 82₁, 82₂, 84₁, and 84₂ and Y-axis linear motors 80 and 81 constitute wafer stage drive section 124′. Each of the linear motors above constituting wafer stage drive section 124′ is controlled by stage controller 19 under the instructions of main controller 20.

In the second embodiment, the configuration of the wafer stages WST1 and WST2 is to be virtually the same as the configuration of wafer stage WST in the first embodiment (refer to FIG. 3), and in each component of wafer stage WST1 (WST2) in FIG. 13, an identification number (that is, 1 or 2) that shows the stage to which the component belongs is indicated by a subscript.

Returning to FIG. 11, at positions on the +X side and −X side of projection optical system PU equally apart, the off-axis alignment systems (hereinafter, abbreviated in an “alignment system”) ALG1 and ALG2 are severally disposed. Alignment systems ALG1 and ALG2 are actually attached to holding members that hold projection optical system PU. As such alignment systems ALG1 and ALG2, for example, a sensor of an FIA (Field Image Alignment) system by an image processing method is used. This sensor irradiates a broadband detection beam that does not expose the resist on the wafer onto a target mark, picks up an image of the target mark formed on a light receiving plane by the reflected light from the target mark and an image of an index (not shown) (an index pattern on an index plate arranged inside alignment systems ALG1 and ALG2 by using an imaging device (such as a CCD), and outputs their imaging signals. As alignment systems ALG1 and ALG2, the system is not limited to the FIA system, and it is naturally possible to use an alignment sensor that irradiates a coherent detection light onto the target mark and detects scattered light or diffracted light generated from the target mark, or a sensor that detects two diffracted lights (for example, diffracted light of the same order or diffracted light that diffract in the same direction) generated from the target mark by making them interfere with each other, independently, or appropriately combined.

In the embodiment, alignment system ALG1 is used for measuring the position of alignment marks formed on wafer W1, fiducial marks formed on fiducial mark plate FM1, and the like. Further, alignment system ALG2 is used for measuring the position of alignment marks formed on wafer W2, fiducial marks formed on fiducial mark plate FM2, and the like.

Information from these alignment systems ALG1 and ALG2 is to be supplied to main controller 20.

Next, the configuration or the like of wafer interferometer system 18′ will be described, referring to FIG. 13. As is shown in FIG. 13, the wafer interferometer system 18′ has three Y-axis interferometers 18Y_{M}, 18Y_{R}, and 18Y_{L} that severally have measurement axes BIYM, BIYR, and BIYL. The measurement axes are in parallel with the Y-axis, and respectively pass through the projection center (optical axis AX) of projection optical system PL, the detection center of alignment system ALG1, and the detection center of alignment system ALG2. Wafer interferometer system 18′ also has two X-axis interferometers 18X₂ and 18X₁ that severally have measurement axes BI2X and BI1X. The measurement axes are in parallel to the X-axis, and respectively join the detection center of projection optical system PL (optical axis AX) and the detection center of alignment system ALG1, and the detection center of projection optical system PL (optical axis AX) and the detection center of alignment system ALG2

Herein, when wafer stage WST1 is in an area (a first area) near a position (a first position) directly under projection optical system PL and a wafer on wafer stage WST1 is exposed, X-axis interferometer 18X₁ and Y-axis interferometer 18Y_{M} control the position of wafer stage WST1. In the following description, a coordinate system set by the measurement axes of X-axis interferometer 18X₁ and the Y-axis interferometer 18Y_{M} will be referred to as a first exposure coordinate system.

Further, when wafer stage WST2 is in the first area described above and the wafer on wafer stage WST2 is exposed, the position of wafer stage WST1 is controlled by X-axis interferometer 18X₂ and Y-axis interferometer 18Y_{M}. In the following description, a coordinate system set by the measurement axes of the X-axis interferometer 18X₂ and the Y-axis interferometer 18Y_{M} will be referred to as a second exposure coordinate system.

Further, when wafer stage WST1 is in an area (a second area) near a position directly under the detection center of the alignment system ALG1, and detection of an alignment mark formed on the wafer on wafer stage WST1, such as wafer alignment (to be described later), is performed, X-axis interferometer 18X₁ and Y-axis interferometer 18Y_{R} control the position of wafer stage WST1. In the following description, a coordinate system set by the measurement axes of X-axis interferometer 18X₁ and Y-axis interferometer 18Y_{R} is called a first alignment coordinate system.

Further, when wafer stage WST2 is in an area (a third area) near a position directly under the detection center of the alignment system ALG2 and detection of an alignment mark formed on the wafer on wafer stage WST2, such as wafer alignment (to be described later), is performed, X-axis interferometer 18X₂ and Y-axis interferometer 18Y_{L} control the position of wafer stage WST2. In the following description, a coordinate system set by the measurement axes of X-axis interferometer 18X₂ and Y-axis interferometer 18Y_{L} is called a second alignment coordinate system.

X-axis interferometers 18X₂ and 18X₁ described above are multi-axis interferometers having a plurality of optical axes, and the output values of each optical axis can be measured independently. Therefore, besides measuring the position of wafer stages WST1 and WST2 in the X-axis direction, X-axis interferometers 18X₂ and 18X₁ can measure the rotation amount around the Y-axis (rolling amount) and the rotation amount around the Z-axis (yawing amount).

Further, Y-axis interferometers 18Y_{M}, 18Y_{R}, and 18Y_{L} described above, for example, are dual-axis interferometers each having two optical axes, and the output values of each optical axis can be measured independently. Therefore, besides measuring the position of the wafer stages WST1 and WST2 in the Y-axis directions, Y-axis interferometers 18Y_{M}, 18Y_{R}, and 18Y_{L} can measure the rotation amount around the X-axis (pitching amount).

Further, the multi-axis interferometers described above may detect positional information related to the optical axis direction (the Z-axis direction) of projection optical system PL, by irradiating laser beams on a reflection surface arranged on the frame on which projection optical system PL is mounted (not shown), via reflection surfaces arranged on wafer stages WST1 and WST2 at an inclination of 45°.

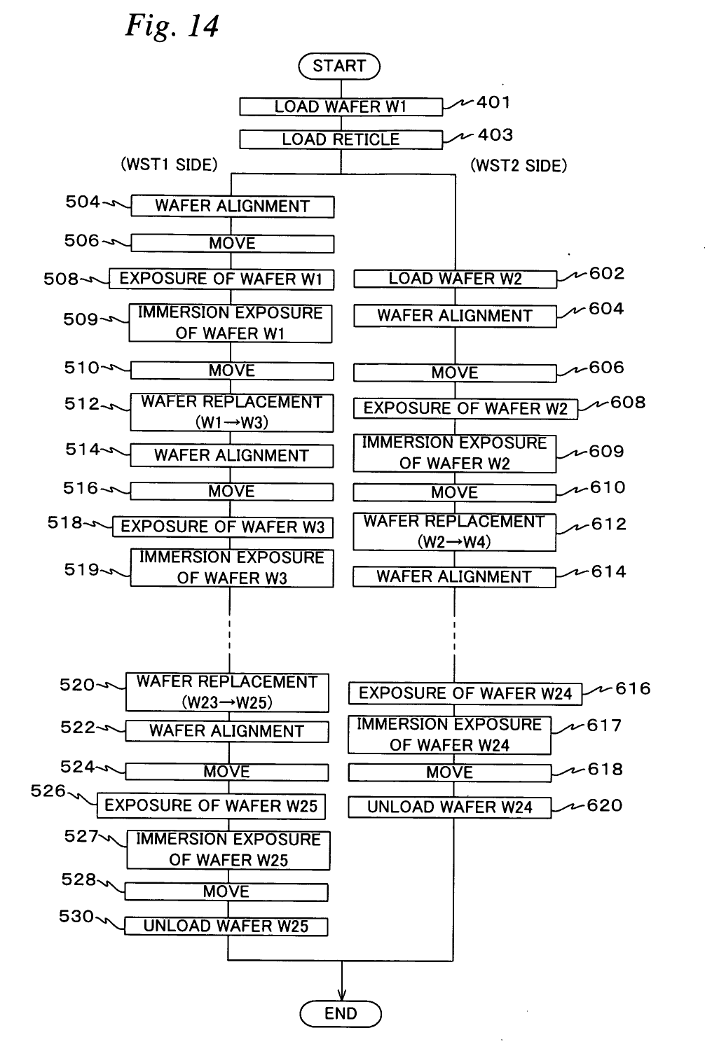

Next, a parallel processing operation (double exposure operation) of wafers in one lot in exposure apparatus 100 related to the second embodiment will be described according to FIG. FIG. 14, which shows an operation in an exposure apparatus main body centering on projection optical system PL in chronological order, while appropriately referring to other drawings.

As a premise, the first wafer, wafer W1 out of the wafers in one lot, is to be carried to the C/D by a carrier system (not shown) and is to be coated with a photosensitive agent (chemically amplified resist) by a coater. Then, also to the second wafer, wafer W2, the third wafer, wafer W3, and so forth, up to the 25^{th} wafer, wafer W25, the resist is to be coated by the coater of the C/D, independently from the processing shown in the flowchart in FIG. 14. Further, also in the second embodiment, the resist that is coated is to be a positive resist. Further, as in the first embodiment above, wafers W1 to W25 subject to exposure are to be wafer on which shot areas are already formed.

First of all, in step 401 of FIG. 14, the first wafer, wafer W1 is loaded on wafer stage WST1. Herein, wafer stage WST1 moves to a right-side loading position, and a carrier system (not shown) performs loading of wafer W1. The positional control of wafer stage WST1 near the right-side loading position is performed based on the measurement values of interferometers 18X₁ and 18X₂ severally having measurement axes BI1X and BIYR.

In the next step, step 403, reticles 9A and 9B are loaded on reticle stage RST′ . Reticles 9A and 9B are arranged as is shown in FIG. 12 by this loading.

In the second embodiment, the right-side loading position is determined so that fiducial mark plate FM₁ of wafer stage WST1 is located directly under alignment system ALG1 when wafer stage WST1 is at the right-side loading position. Prior to wafer stage WST1 moving to the right loading position, interferometer 18Y_{R} begins to measure the position of wafer stage WST1 at some point when the interferometer beam from interferometer 18Y_{R} having the measurement axis BIYR falls on movable mirror 17Y₁.

In the state where wafer stage WST1 is at the right-side loading position, alignment system ALG1 takes in the image of the fiducial mark, and its image signal is sent to main controller 20. Main controller 20 applies a predetermined processing to the image signal, and by analyzing the signal after the processing, detects the position of the fiducial mark using the index center of alignment system ALG1 as a datum. Main controller 20 computes the coordinate position of the fiducial mark on fiducial mark plate FM₁ in the first alignment coordinate system, based on the position of the fiducial mark and the measurement results of interferometers 18X₁ and 18Y_{R} that severally have measurement axes BI1X and BIYR.

Following the wafer loading, reticle loading, and positional measurement of the fiducial mark described above, in step 504 of FIG. 14, wafer alignment by the EGA method such as the one disclosed in, for example, Kokai (Japanese Unexamined Patent Application Publication) No. 61-44429 and the corresponding U.S. Pat. No. 4,780,617 or the like is performed to obtain the arrangement of each shot area on wafer W1. To be more specific, alignment system ALG1 measures alignment mark (sample mark) positions of a predetermined sample shot area on wafer W1, while interferometers 18X₁ and 18Y_{R} (measurement axes (BI1X, BIYR) control the position of wafer stage WST1 and wafer stage WST1 is sequentially moved based on the design shot arrangement data (alignment mark positional data). And then, based on the measurement results, the measurement values of interferometers 18X₁ and 18Y_{R} when measuring each sample mark, and design coordinate data of the shot arrangement, the arrangement data for all the shots is calculated by statistical calculation by the least-squares method. Consequently, the coordinate position of each shot area is calculated on the first alignment coordinate system. Stage controller 19 controls the operation of each section when the EGA is performed, operating under the control of main controller 20. Main controller 20 performs the calculation described above.

Then, by subtracting the coordinate position of the fiducial mark from the coordinate position of each shot area, main controller 20 calculates the relative positional relationship of each shot area to the fiducial mark.

While operations such as wafer exchange described above (in this case, loading of wafer W1) and alignment are being performed on the wafer stage WST1 side, wafer stage WST2 is in a waiting state.

Wafer stage WST2 in the waiting state is positioned at a left-side loading position. The left-side loading position is at a position where fiducial mark plate FM₂ can be located under alignment system ALG2. Before wafer stage WST2 moves to the left-side loading position, positional measurement of wafer stage WST2 by interferometer 18Y_{L} begins at some point when the interferometer beam having the measurement axis BIYL from interferometer 18Y_{L} falls on movable mirror 17Y₂.

Next, in step 506 of FIG. 14, wafer stage WST1 is moved from the right-side loading position to a position where the fiducial mark on fiducial mark plate FM₁ is brought directly under the optical axis AX center (projection center) of projection optical system PL shown in FIG. 13 (hereinafter, referred to as “the first exposure reference position” for the sake of convenience). During this movement, the interferometer beam having measurement axis BIYR from interferometer 18Y_{R} goes off from movable mirror 17Y₁, and the interferometer beam having measurement axis BIYM from interferometer 18Y_{M} falls on movable mirror 17Y₁. Therefore, before wafer stage WST1 reaches the first exposure reference position described above, positional measurement of wafer stage WST1 by interferometer 18Y_{M} begins at some point when the interferometer beam having measurement axis BIYM from interferometer 18Y_{M} hits movable mirror 17Y₁. In the following description, for the sake of simplicity, details on the operations of the interferometers associated with the movement of wafer stages WST1 and WST2 will be omitted unless particularly necessary.

Then, after wafer stage WST1 moves to the first exposure reference position, main controller 20 detects the positional relation between the fiducial mark on fiducial mark plate FM₁ and the projected image on the wafer surface of the reticle alignment mark formed on reticle 9A corresponding to the fiducial mark, by a pair of reticle alignment systems (not shown) using exposure light IL in a state where there is no water Lq on the image plane side of projection optical system PL′.

Prior to performing the relative position detection described above (taking in the image signal of each mark image by the reticle alignment system), main controller 20 begins monitoring the Y position of wafer stage WST1 with interferometer 18Y_{M} having measurement axis BIYM.

Thus, the positional relation between the exposure position (the pattern projection position by projection optical system PL′) in the dry state in the coordinate system (the first exposure coordinate system) using the measurement axes BI1X and BIYM and the coordinate position of the fiducial mark on fiducial mark plate FM₁ is obtained.

From the positional relation of each shot with respect to the fiducial mark on fiducial mark plate FM₁, which has been obtained in advance, and the positional relation between the exposure position and the coordinate position of the fiducial mark on fiducial mark plate FM₁, main controller 20 finally calculates the positional relationship between the exposure position and each shot. And according to the results, the dry exposure of each shot area on wafer W1 is performed.

Next, in step 508 of FIG. 14, dry exposure by a step-and-scan method is performed on each shot area on wafer W1 on wafer stage WST1 by using reticle 9A in a state where there is no liquid on the image plane side of projection optical system PL′ in the following manner.

More specifically, main controller 20 gives instructions to stage controller 19 based on the positional relation between the exposure position and each shot area calculated in step 506 and controls each linear motor constituting reticle stage drive section 11 and wafer stage drive section 124′, while monitoring the measurement values of each measurement axis of Y-axis interferometer 18Y_{M} and X-axis interferometer 18X₁.

Stage controller 19, particularly during the scanning exposure of each shot area on wafer W1, performs synchronous control between reticle stage RST′ and wafer stage WST1 in order to maintain the moving velocity Vr of reticle stage RST′ in the Y-axis direction and the moving velocity Vw of wafer stage WST1 in the Y-axis direction at a velocity ratio in response to the projection magnification (¼ times or ⅕ times) of projection optical system PL. Main controller 20 controls the illumination operation by illumination system 10 in accordance with the control between reticle stage RST′ and wafer stage WST1 described above, similar to a regular scanner.

In the next step, step 509, the immersion exposure to wafer W1 using reticle 9B is performed under the control of main controller 20. First, main controller 20 moves reticle stage RST′ via stage controller 19 so that reticle 9B on reticle stage RST′ corresponds to illumination area IAR. Then, main controller 20 controls the open/close of each valve of liquid supply unit 5 and liquid recovery unit 6 of liquid supply/drainage system 32, and starts the supply and collection of water to/from the space between tip lens 42 and wafer W1. Accordingly, a constant amount of water Lq is supplied to the space in a stable state at all times.

Then, main controller 20 detects the relative position between the fiducial mark on fiducial mark plate FM₁ and the reticle alignment mark on reticle 9A corresponding to the fiducial mark via water Lq by the pair of reticle alignment system (not shown) using exposure light IL. Thus, the relative positional relationship between the exposure position (the projected position of a pattern via water Lq by projection optical system PL′) in an immersed state in the coordinate system using measurement axes BI1X and BIYM and the coordinate position of the fiducial mark on fiducial mark plate FM₁ is obtained. A correction mechanism may be provided so that the reticle alignment system can detect marks at a desired accuracy both in the state where water Lq exists (an immersed state) and the state where there is no water Lq (a dry state). Further, the reticle alignment system may be provided separately for measurement in the immersed state and for measurement in the dry state.

Then, main controller 20 computes the relative positional relationship between the exposure position in the immersed state and each shot area on wafer W1, based on the relative positional relationship of each shot area to the fiducial mark on fiducial mark plate FM₁ obtained earlier, and the relationship between the fiducial mark on fiducial mark plate FM₁ and the exposure position in the immersed state.

Then, main controller 20 controls the stage control operation and the illumination operation by illumination system 10 similar to step 508, and based on the relative positional relationship computed earlier between the exposure position in the immersed state and each shot area, performs scanning exposure of each shot area on wafer W1 via water Lq while controlling the movement of reticle stage RST′ and wafer stage WST1. In order to execute the immersion exposure and the dry exposure using projection optical system PL′ at a desired image forming performance, the image forming characteristics (such as focusing) of projection optical system PL′ may be corrected by image forming characteristic correction controller 181 or the like, or a part of the optical members of projection optical system PL′ may be switched depending on the immersion exposure and the dry exposure.

With this method, in exposure apparatus 100, the pattern of pattern area PA2 on reticle 9B is transferred by the immersion method with high accuracy onto each shot area on wafer W1, on which the pattern on reticle 9A was transferred. The wavelength of exposure light IL is substantially shortened by water Lq between projection optical system PL and wafer W1, and reticle 9B is transferred onto wafer W1 at a higher resolution than reticle 9A. It is a matter of course that liquid supply to the space between tip lens 42 and wafer W1 by liquid supply/drainage system 32 is controlled along with the movement of the XY plane of wafer W1, similar to the first embodiment. More specifically, during the exposure operation by the step-and-scan method to each shot area of wafer W1, main controller 20 controls the open/close of each valve of liquid supply unit 5 and liquid recovery unit 6 of liquid supply/drainage system 32 in response to the changes of the moving direction of wafer W1 in the same manner as in the first embodiment, and during the exposure operation by the step-and-scan method to wafer W1, a constant amount of water Lq between tip lens 42 and wafer W1 is held stable at all times. Further, when the immersion exposure of each shot area on wafer W1 is completed, main controller 20 stops water supply by liquid supply/drainage system 32 and completely collects the water Lq filled in the space on the image plane side of projection optical system PL′.

As is described, while the exposure (exposure using reticles 9A and 9B) to wafer W1 on wafer stage WST1 is being performed in step 508 and step 509 of FIG. 14, loading and alignment of the second wafer, wafer W2, is performed on wafer stage WST2 in steps 602 and 604.

The positional control of wafer stage WST2 in this case is performed based on the measurement values of interferometers 18X₂ and 18Y_{L} severally having the measurement axes BI2X and BIYL, that is, on the second alignment coordinate system.

Then, in the exposure operation and the wafer exchange/alignment operation, which are parallelly performed on the two wafer stages, WST1 and WST2, the wafer stage that completes the operations first moves into a stand-by state, and then after both operation are completed, the procedure proceeds to step 510 and step 606 where wafer stage WST1 moves to the right-side loading position and wafer stage WST2 moves to the exposure position (or to be more precise, the second exposure reference position).

Then, on wafer stage WST1, which has finished moving in step 510, wafer exchange (wafer W1→wafer W3) is performed at the right-side loading position in step 512, and exposure operation in the dry state is performed in step 608 to each shot area of wafer W2 on wafer stage WST2, which has finished the alignment operation in step 604, in the same manner as instep 508 described above. At this point, reticle stage RST′ is to be moved so that reticle 9A corresponds to illumination area IAR, and the positional control of wafer stage WST2 is performed based on the measurement values of the interferometers 18X₂ and 18Y_{M} severally having the measurement axes BI2X and BIYM, that is, on the second alignment coordinate system. In the next step 609, immersion exposure to each shot area of wafer W2 is performed in the same manner as step 509 described above. At this point, reticle stage RST′ is to be moved so that reticle 9B corresponds to the illumination area IAR, and liquid supply by liquid supply/drainage system 32 is performed.

Herein, in step 512, wafer W1 unloaded from wafer stage WST1 is carried to the C/D by a carrier system (not shown), PEB is performed on wafer W1 by the bake unit, and then is developed in the developer. Due to the PEB, in the resist on wafer W1, for example, a dissolution restrainer is desorbed from the base resin, and alkali solubility appears on the exposed area and a latent image of the transferred pattern is formed on wafer W1. Then, by the development, the area that has become soluble is removed, and the image of the transferred pattern (the pattern image shown in FIG. 6, for example) is formed on wafer W1.

Then, while exposure of wafer W2 on wafer stage WST2 is performed in step 608 and step 609, wafer alignment of wafer W3 is executed on the other wafer stage, WST1, in step 514.

Then, after the exposure operation on wafer stage WST2 is completed, the moving (switching) of the both wafer stages WST1 and WST2 is performed in steps 516 and 610, and in the processing that follows, the dry exposure operation to wafer W3 using reticle 9A (step 518) and the immersion exposure using reticle 9B (step 519), and the wafer exchange (W2→W4) and wafer alignment (step 612, 614) on wafer stage WST2 are performed in parallel. In this case as well, wafer W2 unloaded from wafer stage WST2 is carried to the C/D by a carrier system (not shown), PEB is performed on wafer W2 by the bake unit, and then is developed in the developer.

Then, the parallel processing using the two wafer stages WST1 and WST2 is repeatedly performed. Then, a wafer to which exposure was performed on wafer stage WST1 in the odd-numbered order is carried to the C/D by the carrier system (not shown), PEB is performed on the wafer by the bake unit, and then is developed in the developer, while a wafer to which exposure was performed on wafer stage WST2 in the even-numbered order is carried to the C/D by the carrier system (not shown), PEB is performed on the wafer by the bake unit, and then is developed in the developer.

Then, the operations described above are repeated, and while on the wafer stage WST2 side, in step 616, exposure to a wafer W24 is performed by using reticle 9A, and in step 617, the immersion exposure to wafer W24 is performed by using reticle 9B, on the wafer WST1 side, in steps 520 and 522, a wafer W23 is exchanged with a wafer W25 and the alignment of wafer W25 is performed.

Furthermore, at the point where the moving of both wafer stages WST1 and WST2, or in other words, switching is performed in steps 524 and 618 and wafer stage WST2 is located on the left-side loading position, in step 620, wafer W24 is unloaded from wafer stage WST2 (PEB and development are performed after that). Then, wafer stage WST2 moves into a waiting state.

Meanwhile, the exposure operation (pattern transfer of reticle 9A) and the immersion exposure operation (pattern transfer of reticle 9B) to the last wafer W25 in the one lot are performed on wafer stage WST1 in step 526 and step 527 in the same manner as in the previous wafers. Then, after the exposure has been completed, in step 528, wafer stage WST1 is moved to the right loading position, and in step 530, wafer W25 is unloaded (PEB and development are performed after that).

When the transfer of a pattern on reticle 9A by a normal exposure, the transfer of a pattern on reticle 9B by the immersion exposure, and PEB and development of the wafers in the one lot (=25 pcs) are completed in the manner described above, the processing ends.

As is described in detail above, according to exposure apparatus 100 related to the second embodiment, in the case of performing double exposure to the same resist layer of wafers W1 to W25, in one exposure of the double exposure, water Lq is supplied in the space between projection optical system PL, which irradiates exposure light IL to wafers W1 to W25, and wafers W1 to W25, so as to make the substantial wavelength of exposure light IL in the space differ from the wavelength of exposure light IL in the space in the other exposure. With this method, for example, in the exposure where a high resolution is required, such as in the exposure using reticle 9B, the substantial wavelength of exposure light IL in the space between projection optical system PL and wafers W1 to W25 can be shortened, whereas in the exposure where the required resolution does not have to be so high (exposure using reticle 9A), the substantial wavelength of exposure light IL can be made longer to a certain level. In the exposure where the substantial wavelength of exposure light IL is shortened, such as in for example, the immersion exposure, the time required for exposure tends to be longer than normal exposure due to operations such as supplying the liquid. Accordingly, when the exposure method of the second embodiment is employed, an temporally advantageous exposure according to the resolution required in each exposure can be performed, even in the case where a plurality of exposures is performed, therefore, an exposure that satisfies both high accuracy and high throughput can be attained similar to the first embodiment. In addition, since the dissolution of acid can also be reduced, exposure with high precision can be achieved, similar to the first embodiment.

In the second embodiment above, the dry exposure and the immersion exposure were performed in succession to the same wafer in the second embodiment; however, the present invention is not limited to this. For example, the dry exposure may be performed per one lot, and the immersion exposure can be performed after the dry exposure. Further, for example, after performing the dry exposure to the wafer on wafer stage WST1, wafer stage WST1 may be withdrawn once and the dry exposure may be performed to the wafer on wafer stage WST2. And then, wafer stage WST1 may be moved below projection optical system PL again, and after immersion exposure has been performed to the wafer on the stage, the immersion exposure may be performed to the wafer on wafer stage WST2.

Although in the second embodiment described above, the exposure apparatus was an exposure apparatus of a double stage (twin stage) type having two wafer stages WST1 and WST2, the apparatus may be an exposure apparatus of a single-stage type. Further, an exposure apparatus equipped with three or more wafer stages may be used, or an exposure apparatus equipped with a projection optical system and an alignment system and also including two ore more wafer stages as is disclosed in, Kohyo (Japanese Unexamined Patent Application Publication) No. 2000-511704 and the corresponding U.S. Pat. No. No. 6,262,796 or the like, may be used. Or, as is disclosed in, for example, Kokai (Japanese Unexamined Patent Application Publication) No. 2000-164504 (the corresponding U.S. patent application Ser. No. 09/593,800), an exposure apparatus equipped with a measurement stage that has measurement members and sensors installed and moves on the image plane of the projection optical system, separately from the wafer stages for holding wafers, may be used.

Further, in the case of performing multiple exposure including the immersion exposure and the dry exposure by using one projection optical system, a part of the projection optical system may be replaced depending on whether the immersion exposure or the dry exposure is performed.

Furthermore, in the second embodiment described above, the exposure apparatus equipped with two wafer stages with respect to one projection optical system is used, however, an exposure apparatus including two or more projection optical systems may also be used. In such a case, the apparatus may be equipped with one wafer stage, two wafer stages or more.

Further, in the second embodiment described above, similar to the first embodiment previously described, exposure using the immersion method is performed after normal exposure to which the immersion method is not applied, which can reduce the time until PEB after exposing a finer pattern, so that adverse effect such as contamination after exposure can be minimized, however, this order of exposure may be reversed. In this case, when compared to the case described above where the immersion exposure, which is the second exposure, is performed after performing the first exposure (after the acid generated on the wafer becomes easily soluble), because the immersion exposure is performed in the first exposure, dissolution of the acid generated on wafer W into liquid (water) can be reduced.

Whether the immersion exposure should be performed on the first time or the second time may be decided depending on various process conditions, such as emphasis should be placed on reducing the time until PEB is applied after the immersion exposure (after exposure by exposure light having shorter actual wavelength) or emphasis should be placed on the dissolution of acid during the immersion exposure, as in the first exposure described above.

Further, in the second embodiment described above, by performing the exposure once of the double exposure in a state where liquid there is no liquid filled in the space between the projection optical system (tip lens) and the wafer or the like, and the other exposure is performed in a state where liquid is held in the space between the projection optical system (tip lens) and the wafer, the substantial wavelength of the exposure light in the space between the projection optical system (tip lens) and wafer W is made to be different between the first exposure in the double exposure and the other exposure. However, the immersion exposure may be executed in both exposures in the double exposure. In this case, the liquid supplied on the wafer in each immersion exposure may be changed. More specifically, the liquid supply/drainage system may be constituted so that a plurality of types of liquid (naturally, pure water may be included in them) can be supplied, and any one of the plurality of types of liquid may be selected by the control of main controller 20. In such a liquid supply/drainage system, the liquid supply unit and the liquid collection unit may be arranged for each liquid and each nozzle may also be arranged separately for each liquid. In this case, as the plurality of types of liquid, liquids that have a different refractive index to exposure light IL has to be selected. Further, the liquid to be supplied on the second exposure is desirably a liquid that has a low solubility of acid.

Furthermore, as is described in the first embodiment above, the substantial wavelength of the exposure light in the space between the projection optical system (tip lens) and the wafer may be made to differ between one exposure in the double exposure and the other exposure by changing the oscillation wavelength of the light source. In this case, both exposures in the double exposure may be performed in a dry state, or in an immersed state, or the first exposure may be performed in a dry state and the other exposure may be exposed in an immersed state.

Further, in each of the embodiments described above, the exposure method was suggested in which the dissolution of acid generated from the photo acid generator contained within the resist was minimized. However, the present invention is not limited to this, and it is a matter of course that the present invention is effective in reducing, for example, the dissolution of the base resin contained within the chemically amplified resist, the dissolution of specific substances contained within the resist such as the dissolution inhibitor, the crosslinking agent or the like. Further, even in the case of using a resist other than the chemically amplified resist, the present invention is effective in reducing the dissolution of a material contained within the resist.

Further, in each of the embodiments above, in the case of performing the double exposure (multiple exposure), which includes the dry exposure in a state where liquid there is no liquid in the space between the projection optical system and the wafer or the like and the immersion exposure in a state where liquid is held in the space between the projection optical system and the wafer or the like, it is desirable to use a resist for immersion exposure.

Further, in each of the embodiments above, the double exposure was performed using a phase shift method and using a reticle serving as a halftone phase shift mask. This is because an L/S pattern B1 can be transferred onto the wafer with good accuracy. However, the present invention is not limited to this, and the phase shift area on L/S pattern B1 of reticle 9B may be a light shielding pattern. In other words, in each of the embodiments above, the gate pattern was transferred using the phase shift method, however, the present invention is not limited to this, and exposure may be performed using a typical mask. The point is, to fine patterns such as L/S pattern B1, pattern transfer should be performed at a resolution where the pattern can be transferred with good accuracy. That is, in the case the line width of the L/S pattern is dY1, the substantial wavelength of exposure light IL should be set to a wavelength according to the resolution in which the pattern can be transferred with good precision. Further, in each of the embodiments above, as reticle 9B, other types of phase shift masks such as a Levenson type phase shift mask may be used.

Further, the present invention can be also applied to a multiple exposure, such as triple exposure or more. For example, triple exposure can be performed using a reticle on which a wiring pattern is formed, in addition to reticle 9A and reticle 9B. Even in this case, in at least one exposure, the substantial exposure wavelength reaching the wafer should be different from other exposures. In this case as well, if the number of wafers in one lot is set based on the time where the performance of the photosensitive agent can be maintained, a similar effect can be obtained as in the description above. Further, in the multiple (double) exposure in each of the embodiments described above, the projected image of the pattern of reticle 9A and the projected image of the pattern of reticle 9B are projected on the same position (the same shot area) on the wafer, but the projected image of the pattern of reticle 9A and the projected image of the pattern of reticle 9B may be projected on different positions on wafer W so that, for example, the image only partially overlaps.

Further, the multiple exposure in each of the embodiments above and a so-called modified illumination method (for example, SHRINC: Super High Resolution by Illumination Control) maybe used in combination. For example, when transferring a periodic pattern such as L/S pattern B1 on reticle 9B, if a double-polar illumination aperture stop or the like where each aperture stop is arranged corresponding to the arrangement direction of L/S pattern B1 is used as an illumination system aperture stop in illumination system 10, resolution and depth of focus can be further improved. Further, in the circuit pattern, periodic patterns such as the L/S pattern usually exist in countless numbers, and these periodic patterns can be decomposed so as to make a reticle, on which periodic patterns arranged in the X-axis direction are formed, and a reticle, on which periodic patterns arranged in the Y-axis direction are formed, and the multiple exposure may be performed using these reticles. In this case, in each exposure, the double-polar illumination aperture stop along the arrangement direction of the periodic patterns is to be used as the illumination system aperture stop. In the case there are patterns requiring different resolutions (that is, different sizes) in the periodic patterns of the same arrangement direction, the patterns of the different sizes are to be formed on separate reticles, and the pattern on each reticle should be transferred by normal exposure and by an exposure where the substantial wavelength of the exposure light is different, such as in the immersion exposure.

Further, as is previously described, pattern formation by the chemically amplified resist (formation of a latent image before development processing) is performed in two steps, by acid generation due to exposure and by acid catalytic reaction during PEB. Therefore, the stability of acid, which is a catalyst, is a critical problem. In each of the embodiments above, the method of reducing the dissolution of acid in the immersion exposure in the multiple exposure was suggested, but besides such a problem, the so-called deactivation of acid also becomes a problem, in which basic substances such as ammonia in a clean room atmosphere adsorb on the resist surface to cause a neutralizing reaction with the acid on a surface layer. That is, in an exposure process, a mechanism to prevent basic substances from adsorbing on the resist is necessary. As such a mechanism, a method such as installing a filter capable of removing basic substances in the exposure apparatus and further coating protective film against basic substances on the resist surface can be considered, but in the case of performing the immersion exposure as in each of the embodiments above, using liquid into which basic substances are hard to dissolve as liquid used in the immersion exposure, for example, is considered.

Further, in each of the embodiments above, ultra pure water (water) was used as the liquid, but the present invention is not limited to this as is described above. As the liquid, liquid that is chemically stable, has high transmittance to exposure light IL and safe to use, such as a fluorine containing inert liquid may be used. As such as a fluorine-containing inert liquid, for example, Fluorinert (the brand name of 3M United States) can be used. The fluorine-containing inert liquid is also excellent from the point of cooling effect. Further, as the liquid, a liquid which has high transmittance to illumination light IL and a refractive index as high as possible, and furthermore, a liquid which is stable against the projection optical system and the photoresist coated on the surface of the wafer (for example, cederwood oil or the like) can also be used. Further, in the case the F₂ laser is used as the light source, a fluorine containing liquid (such as fomblin oil) may be used.

Further, in each of the embodiments above, the liquid that has been recovered may be re-used, and in this case, it is desirable to arrange a filter that removes impurities from the liquid that has been recovered in the liquid collection unit, the recovery pipe or the like.

In each of the embodiments above, tip lens 42 was used as the optical element of projection optical system PL closest to the image plane. However, the optical element is not limited to a lens, and it may be an optical plate (such as a plane-parallel plate) that is used for adjusting aberration (such as spherical aberration, coma, or the like), or may simply be a cover glass. The surface of the optical element of projection optical system PL closest to the image plane side (tip lens 42 in the embodiments above) can be smudged by coming into contact with the liquid (water, in the embodiments above) due to scattered particles generated from the resist by the irradiation of illumination light IL or adherence of impurities in the liquid. Therefore, the optical element is to be fixed freely detachable (exchangeable) to the lowest section of barrel 40, and can be exchanged periodically.

In such a case, when the optical element that comes into contact with the liquid is a lens, the cost for replacement parts is high, and the time required for exchange becomes long, which leads to an increase in the maintenance cost (running cost) as well as a decrease in throughput. Therefore, for example, the optical element that comes into contact with the liquid can be a parallel plane plate, which is less costly than lens 42.

Further, in the exposure apparatus to which the immersion method described above has been applied, the configuration is employed where wafer W is exposed while the optical path space on the light-emitting side of tip lens 42 of projection optical system PL is filled with liquid (pure water) . However, as is disclosed in International Publication No. 2004/019128, the optical path space on the light-incident side of tip lens 42 of projection optical system PL may also be filled with liquid (pure water).

Further, in each of the embodiments above, the range of the liquid (water) flow only has to be set so that it covers the entire projection area (the irradiation area of illumination light IL) of the pattern image of the reticle. Therefore, the size may be of any size; however, on controlling the flow speed, the flow amount and the like, it is preferable to keep the range slightly larger than the irradiation area but as small as possible.

Furthermore, in each of the embodiments described above, auxiliary plates 72a to 72d are arranged in the periphery, however, in some of the present inventions, exposure apparatus that do not necessarily require an auxiliary plate or a flat plate that has a similar function on the wafer stage are available. In this case, however, it is preferable to further provide piping on the wafer stage for recovering the liquid so that the supplied liquid is not spilled from the wafer stage. Further, in each of the embodiments above, the exposure apparatus is employed whose space between projection optical system PL and the wafer is locally filled with liquid. However, the present invention is also applicable to an immersion exposure apparatus whose details are disclosed in, Kokai (Japanese Unexamined Patent Application Publication) No. 06-124873, where a stage holding a substrate subject to exposure is moved in a liquid bath, or to an immersion exposure apparatus whose details are disclosed in, Kokai (Japanese Unexamined Patent Application Publication) No. 10-303114 or Kokai (Japanese Unexamined Patent Application Publication) No. 10-154659 and the corresponding U.S. Pat. No. 5,825,043 or the like, where a wafer is held in a liquid pool of a predetermined depth formed on a stage. As long as the national laws in designated states or elected states, to which this international application is applied, permit, the disclosures cited above in the above publications, and corresponding United States Patent are fully incorporated herein by reference.

The exposure apparatus in each of the embodiments described above can be made by incorporating the projection optical system made up of a plurality of lenses and projection unit PU into the main body of the exposure apparatus, furthermore, and attaching the liquid supply/drainage unit to projection unit PU. Then, along with the optical adjustment operation, parts such as the reticle stage and the wafer stage made up of multiple mechanical parts are also attached to the main body of the exposure apparatus and the wiring and piping connected. And then, total adjustment (such as electrical adjustment and operation check) is performed, which completes the making of the exposure apparatus. The exposure apparatus is preferably built in a clean room where conditions such as the temperature and the degree of cleanliness are controlled.

Further, in each of the embodiments above, the case has been described where the present invention was applied to a scanning exposure apparatus by the step-and-scan method or the like, but it goes without saying that the applicable scope of the present invention is not limited to this. That is, the present invention can also be suitably applied to a reduction projection exposure apparatus by the step-and-repeat method. Further, the present invention can be suitably applied to an exposure of the same resist layer of wafer W in a reduction projection exposure apparatus by the step-and-stitch method in which shot areas are synthesized.

Furthermore, exposure apparatus that has no projection optical system, such as a proximity exposure apparatus and an exposure apparatus by a dual-beam interference method that exposes a wafer by forming interference fringes on the wafer can also be used.

As the usage of the exposure apparatus, it is not limited to exposure apparatus for manufacturing semiconductor devices, and for example, the present invention can be widely applied to an exposure apparatus for manufacturing liquid crystal displays which transfers a liquid crystal display deice pattern onto a square shaped glass plate, and to an exposure apparatus for manufacturing organic EL, thin-film magnetic heads, imaging devices (such as CCDs), micromachines, DNA chips, and the like. Further, the present invention can also be suitably applied to an exposure apparatus that transfers a circuit pattern onto a glass substrate or a silicon wafer not only when producing microdevices such as semiconductors, but also when producing a reticle or a mask used in exposure apparatus such as an optical exposure apparatus, an EUV exposure apparatus, an X-ray exposure apparatus, or an electron beam exposure apparatus.

Further, the light source of the exposure apparatus of each of the embodiments above is not limited to an ArF excimer laser beam light source, and it is also possible to use a pulsed laser light source such as a KrF excimer laser beam light source and an F₂ laser light source, an ultra high pressure mercury lamp that emits an emission line such as a g-line (wavelength: 436 nm) and an i-line (wavelength: 365 nm) or the like. Further, a harmonic wave may also be used that is obtained by amplifying a single-wavelength laser beam in the infrared or visible range emitted by a DFB semiconductor laser or fiber laser, with a fiber amplifier doped with, for example, erbium (or both erbium and ytteribium), and by converting the wavelength into ultraviolet light using a nonlinear optical crystal. Further, the projection optical system is not limited to a reduction system, and the system maybe either an equal magnifying system or a magnifying system. When the light source of each exposure apparatus is diversified in the manner described above, exposure of a plurality of times can be achieved flexibly, according to the resolution that is required.

Device Manufacturing Method

Next, an embodiment will be described of a device manufacturing method that uses exposure apparatus 100, lithography system 110, and the exposure methods described in each of the embodiments above in the lithography step.

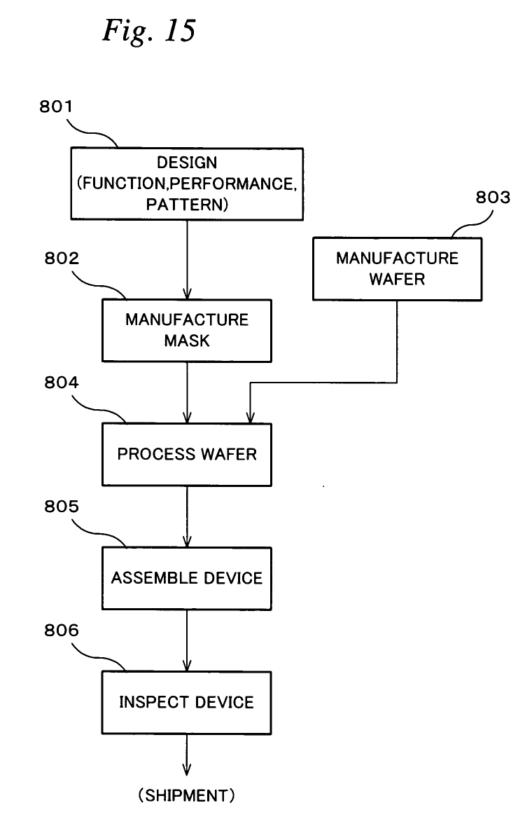

FIG. 15 shows the flowchart of an example when manufacturing a device (a semiconductor chip such as an IC or an LSI, a liquid crystal panel, a CCD, a thin-film magnetic head, a micromachine, and the like). As is shown in FIG. 15, first of all, in step 801 (design step), function and performance design of device (circuit design of semiconductor device, for example) is performed, and pattern design to realize the function is performed. Then, in step 802 (mask manufacturing step), a mask on which the designed circuit pattern is formed is manufactured. Meanwhile, in step 803 (wafer manufacturing step), a wafer is manufactured using materials such as silicon.

Next, in step 804 (wafer processing step), the actual circuit and the like are formed on the wafer by lithography or the like in a manner that will be described later, using the mask and the wafer prepared in steps 801 to 803. Then, in step 805 (device assembly step), device assembly is performed using the wafer processed in step 804. Step 805 includes processes such as the dicing process, the bonding process, and the packaging process (chip encapsulation), and the like when necessary.

Finally, in step 806 (inspection step), tests on operation, durability, and the like are performed on the devices made in step 805. After these steps, the devices are completed and shipped out.

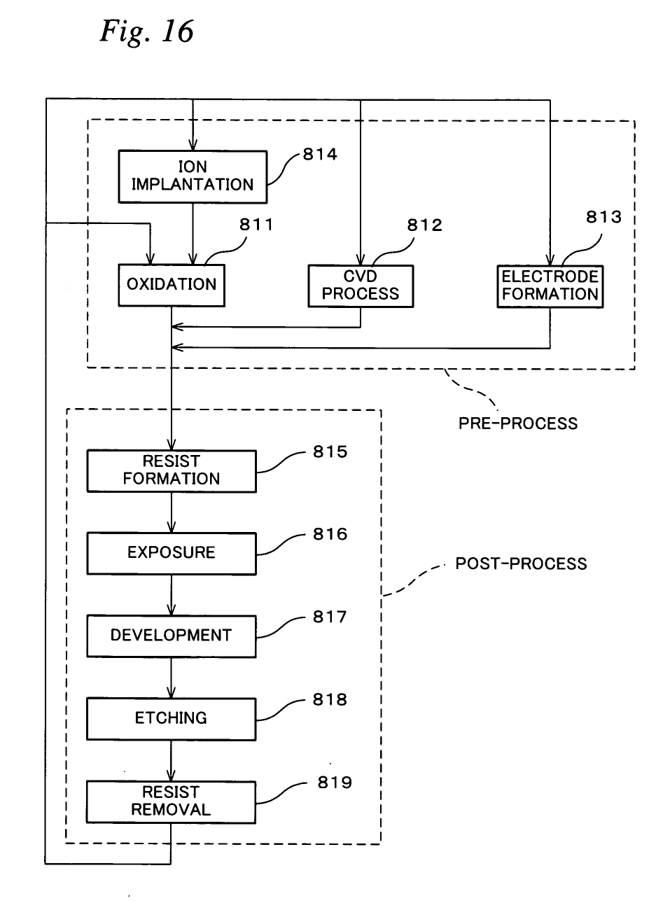

FIG. 16 is a flow chart showing a detailed example of step 804 described above. Referring to FIG. 16, in step 811 (oxidation step), the surface of wafer is oxidized. In step 812 (CDV step), an insulating film is formed on the wafer surface. Instep 813 (electrode formation step), an electrode is formed on the wafer by deposition. In step 814 (ion implantation step), ions are implanted into the wafer. Each of the above steps 811 to 814 constitutes the pre-process in each step of wafer processing, and the necessary processing is chosen and is executed at each stage.

When the above-described pre-process ends in each stage of wafer processing, post-process is executed as follows. In the post-process, first in step 815 (resist formation step), a photosensitive agent is coated on the wafer. Then, in step 816 (exposure step), the circuit pattern of the mask is transferred onto the wafer by the lithography system (exposure apparatus) and the exposure method of the embodiment above. Next, in step 817 (development step), the PEB described above is performed and the wafer that has been exposed is developed in the C/D of exposure apparatus l00ᵢ (or 100), and in step 818 (etching step), an exposed member of an area other than the area where resist remains is removed by etching. Then, in step 819 (resist removing step), when etching is completed, the resist that is no longer necessary is removed.

By repeatedly performing the pre-process and the post-process, multiple circuit patterns are formed on the wafer.

When the device manufacturing method of the embodiment described in the description above is used, because lithography system 100 equipped with exposure apparatus 100ᵢ or exposure apparatus 100 and the exposure method in the embodiment above will be used in the exposure step (step 816), the throughput can be improved and exposure with high precision can be achieved. Accordingly, the productivity (including the yield) of high integration microdevices can be improved.

### INDUSTRIAL APPLICABILITY

As is described above, the exposure method, the exposure apparatus and exposure system of the present invention are suitable for usage in a lithography process for manufacturing semiconductor devices, liquid crystal display devices, or the like, and the device manufacturing method of the present invention is suitable for producing microdevices.

1. An exposure method in which a plurality of times of exposure is performed on a same photosensitive object wherein
the substantial wavelength of an exposure light in a space between a projection optical system, which projects said exposure light on said photosensitive object, and said photosensitive object is different in at least one exposure in said plurality of times of exposure from another exposure.

2. The exposure method according to claim 1 wherein
in said at least one exposure, said space is in a state filled with a predetermined liquid.

3. The exposure method according to claim 2 wherein
in said another exposure, said space is in a state filled with another liquid of a different type from said predetermined liquid.

4. The exposure method according to claim 3 wherein
said predetermined liquid has refractive index larger than the refractive index of said another liquid.

5. The exposure method according to claim 3 wherein
said another liquid has solubility to a specific material contained within a photosensitive agent of said photosensitive object lower than said predetermined liquid.

6. The exposure method according to claim 2 wherein
in said another exposure, said space is in a state not filled with liquid.

7. The exposure method according to claim 6 wherein
said at least one exposure is performed prior to said another exposure.

8. The exposure method according to claim 6 wherein
said at least one exposure is performed after said another exposure is performed.

9. The exposure method according to claim 1 wherein
a wavelength of an exposure light made to enter said projection optical system in said at least one exposure is different from a wavelength of exposure light in said another exposure.

10. The exposure method according to claim 1 wherein
in said at least one exposure, a phase shift method is used.

11. A device manufacturing method including a lithography process wherein
the exposure method of claim 1 is performed to expose a photosensitive object a plurality of times.

12. An exposure method in which a plurality of times of exposure is performed on a same photosensitive object, said method comprising:
a process in which under a first exposure condition where a substantial wavelength of said exposure light in a space between an optical member and said photosensitive object is a first wavelength, said photosensitive object is exposed by said exposure light of said first wavelength; and
a process in which under a second exposure condition where a substantial wavelength of said exposure light in a space between said optical member and said photosensitive object is a second wavelength different from said first wavelength, said photosensitive object is exposed by said exposure light of said second wavelength.

13. The exposure method according to claim 12 wherein
exposure under said first exposure condition is an immersion exposure performed in a state where said space is filled with a predetermined liquid.

14. The exposure method according to claim 13 wherein
exposure under said second exposure condition is an immersion exposure performed in a state where said space is filled with another liquid different from said predetermined liquid.

15. The exposure method according to claim 14 wherein
said predetermined liquid has a refractive index different from said another liquid.

16. The exposure method according to claim 15 wherein
said predetermined liquid has a refractive index larger than said another liquid.

17. The exposure method according to claim 14 wherein
said another liquid has solubility to a specific material contained within a photosensitive agent of said photosensitive object different from said predetermined liquid.

18. The exposure method according to claim 17 wherein
said another liquid has solubility to said specific material contained within said photosensitive agent of said photosensitive object smaller than said predetermined liquid.

19. The exposure method according to claim 13 wherein
exposure under said second exposure condition is a dry exposure performed in a state where said space is not filled with liquid.

20. The exposure method according to claim 19 wherein
said exposure under said first exposure condition is performed prior to said exposure under said second condition.

21. The exposure method according to claim 19 wherein
said exposure under said first exposure is performed after said exposure under said second exposure has been performed.

22. The exposure method according to claim 12 wherein
wavelength of exposure light made to enter said optical member in exposure under said first exposure condition is different from the wavelength of exposure light in exposure under said second exposure condition.

23. The exposure method according to claim 12 wherein
in said exposure under said first exposure condition, a phase shift method is used.

24. The exposure method according to claim 12 wherein
said exposure under said first exposure condition and said exposure under said second exposure condition are severally executed in a different exposure apparatus.

25. The exposure method according to claim 12 wherein
said exposure under said first exposure condition and said exposure under said second exposure condition are severally executed in a same exposure apparatus.

26. A device manufacturing method including a lithography process wherein
the exposure method of claim 12 is performed to expose a photosensitive object a plurality of times.

27. An exposure apparatus that performs a plurality of times of exposure on a same photosensitive object, said apparatus comprising:
a stage that holds said photosensitive object;
a projection optical system that projects an exposure light on said photosensitive object;
an adjustment unit that adjusts a substantial wavelength of said exposure light in a space between said projection optical system and said photosensitive object; and
a control unit that controls said adjustment unit when exposing said photosensitive object a plurality of times so that in at least one exposure of said plurality of times, said substantial wavelength of said exposure light in said space is different from the wavelength in another exposure.

28. The exposure apparatus according to claim 27 wherein
said adjustment unit comprises a liquid supply mechanism that supplies a predetermined liquid so that in a space between said projection optical system and said stage, at least a space between said projection optical system and said photosensitive object on said stage is filled with said liquid, whereby
said control unit controls said adjustment unit so that said liquid supply mechanism supplies said liquid to said space between said projection optical system and said photosensitive object on said stage in said at least one exposure, whereas in said another exposure said liquid supply mechanism does not supply said liquid to said space.

29. The exposure apparatus according to claim 27 wherein
said adjustment unit comprises a liquid supply mechanism that supplies any one liquid of a plurality of types of liquid so that in a space between said projection optical system and said stage, at least a space between said projection optical system and said photosensitive object on said stage is filled with said liquid, whereby
said control unit controls said adjustment unit so that said liquid supply mechanism supplies a predetermined liquid of said plurality of types of liquid to said space between said projection optical system and said photosensitive object on said stage in said at least one exposure, whereas in said another exposure said liquid supply mechanism supplies a liquid different from said predetermined liquid to said space.

30. A device manufacturing method including a lithography process wherein
a device pattern is transferred onto a photosensitive object by using the exposure apparatus according to claim 27.

31. An exposure system that performs exposure on a same photosensitive object a plurality of times, said system comprising:
a first exposure apparatus whose substantial wavelength of an exposure light in a space between a projection optical system, which projects said exposure light on said photosensitive object, and said photosensitive object is a predetermined length; and
a second exposure apparatus whose substantial wavelength of an exposure light in a space between a projection optical system, which projects said exposure light on said photosensitive object, and said photosensitive object is longer than said predetermined length.

32. The exposure system according to claim 31 wherein
in said first exposure apparatus, a predetermined liquid is filled between said projection optical system and said photosensitive object when said exposure light is projected on said photosensitive object.

33. The exposure system according to claim 32 wherein
in said second exposure apparatus, another liquid having a refractive index smaller than said predetermined liquid is filled between said projection optical system and said photosensitive object when said exposure light is projected on said photosensitive object.

34. The exposure system according to claim 32 wherein
in said second exposure apparatus, liquid does not exist between said projection optical system and said photosensitive object when said exposure light is projected on said photosensitive object.

35. The exposure system according to claim 31 wherein
said first exposure apparatus is larger than said second exposure apparatus in number.

36. The exposure system according to claim 31, wherein
oscillation wavelength of a light source emitting said exposure light of said first exposure apparatus is different from oscillation wavelength of a light source emitting said exposure light of said second exposure apparatus.

37. A device manufacturing method including a lithography process wherein
a device pattern is transferred onto a photosensitive object by using the exposure system according to claim 31.
